(19) United States
(12) Patent Application Publication
(10) Pub. No.: US 2017/0287943 A1
(43) Pub. Date: Oct. 5, 2017

(54) HIGH APERTURE RATIO DISPLAY BY INTRODUCING TRANSPARENT STORAGE CAPACITOR AND VIA HOLE

(71) Applicant: Qualcomm Incorporated, San Diego, CA (US)

(72) Inventors: Jia Wei Ma, Taipei (TW); Wei Hsiang Weng, Hsin-Chu (TW); Jan Bos, Hsin-Chu (TW); Cheonhong Kim, San Diego, CA (US)

(21) Appl. No.: 15/136,785

(22) Filed: Apr. 22, 2016

Related U.S. Application Data
(60) Provisional application No. 62/316,364, filed on Mar. 31, 2016.

(51) Int. Cl. H01L 27/12; H01L 29/786; H01L 21/477; H01L 21/46; G09G 3/20; H01L 29/22; H01L 29/423; H01L 29/66; H01L 21/02; H01L 49/02; H01L 29/24

(52) U.S. Cl. CPC H01L 27/127; H01L 27/1255; H01L 28/60; H01L 29/7869; H01L 21/477; H01L 21/46; H01L 29/24; H01L 29/22; H01L 29/42356; H01L 27/1225; H01L 27/1218; H01L 29/66969; H01L 21/02554; H01L 21/02565; H01L 21/02664; G09G 3/2092; G09G 2310/0264; G09G 2300/08; G09G 2330/028

(57) ABSTRACT

This disclosure provides apparatuses and methods of manufacturing apparatuses including thin film transistors (TFTs) and storage capacitors. An apparatus can include a substrate, a TFT, a storage capacitor adjacent to the TFT, and a common electrode. The storage capacitor can be substantially transparent to increase aperture ratio of a display device. The storage capacitor can include an insulating layer between a first transparent electrode and a second transparent electrode. The TFT can include a gate electrode, a gate insulating layer, an oxide semiconductor, source and drain electrodes, and a dielectric layer. The oxide semiconductor can be formed out of the same layer as the first transparent electrode, and the common electrode can be formed out of the same layer as the oxide semiconductor or the source and drain electrodes.

### PRIORITY DATA

This patent document claims priority to co-pending and commonly assigned U.S. Provisional Patent Application No. 62/316,364, titled “High Aperture Ratio Display By Introducing Transparent Storage Capacitor and Via Hole”, by Ma et al., filed on Mar. 31, 2016 (Attorney Docket No. QUALP398PUS/161142P1), which is hereby incorporated by reference in its entirety and for all purposes

### TECHNICAL FIELD

This disclosure relates to charge storage and transfer elements, and more particularly to transparent storage capacitors and transistor structures formed using an oxide semiconductor in display devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Display devices, including but not limited to liquid crystal displays (LCDs), organic light emitting diode (OLED) displays, MEMS displays, plasma displays, cathode ray tubes (CRTs), field emission displays, surface-conduction electron-emitter displays and projection displays, can include an active matrix addressing scheme for providing image data to display elements. Such active matrix display devices can include a thin film transistor (TFT) device and a storage capacitor. The TFT device is a kind of field-effect transistor that includes a source region, a drain region, and a channel region in a semiconducting material. The semiconducting material can include an oxide semiconductor material for improved mobility over amorphous silicon and for simpler manufacturing over polysilicon. The storage capacitor can store charge or voltage during a frame time and/or to speed up device response time. The storage capacitor can include transparent materials to provide more viewable area in the display device.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a substrate and a thin film transistor (TFT), where the thin film transistor includes a gate electrode over the substrate, an oxide semiconductor layer, where the oxide semiconductor layer has a channel region between a source region and a drain region, a first insulating layer between the gate electrode and the oxide semiconductor layer, a source electrode on a source region of the oxide semiconductor layer, a drain electrode on a drain region of the oxide semiconductor layer, and a dielectric layer over the channel region of the oxide semiconductor layer. The apparatus further includes a storage capacitor adjacent to the TFT, where the storage capacitor includes a first transparent electrode over the substrate, where the first transparent electrode has a substantially similar thickness and composition as the oxide semiconductor layer, a second transparent electrode over the first transparent electrode and at least partially overlapping with the first transparent electrode, and a second insulating layer between the first transparent electrode and the second transparent electrode. The apparatus further includes a common electrode, where the common electrode is electrically connected to the first transparent electrode.

In some implementations, the common electrode has a substantially similar thickness and composition as the source and drain electrodes. In some implementations, the common electrode has a substantially similar thickness and composition as the oxide semiconductor layer. In some implementations, the second transparent electrode is electrically connected to the oxide semiconductor layer by a transparent via. In some implementations, the second transparent electrode is electrically connected to the drain electrode by a transparent via. In some implementations, the first transparent electrode and the oxide semiconductor layer share a first common thin film layer, and the common electrode and the source and drain electrodes share a second common thin film layer. In some implementations, the first transparent electrode, the oxide semiconductor layer, and the common electrode share a common thin film layer. In some implementations, the first transparent electrode has a lower electrical resistance than the oxide semiconductor layer in the channel region. In some implementations, the dielectric layer and the second insulating layer share a common thin film layer. In some implementations, the apparatus further comprises an etch stop layer on the oxide semiconductor layer, wherein the etch stop layer is between the oxide semiconductor layer and the dielectric layer.

Another innovative aspect of the subject matter described in this disclosure can be implemented in a method of manufacturing an apparatus, where the apparatus has a TFT region and a storage capacitor region adjacent to the TFT region. The method includes providing a substrate in the TFT and the storage capacitor region, forming a first metal layer on the substrate in the TFT region, forming a first dielectric layer on the first metal layer, forming an oxide semiconductor layer in the storage capacitor region and on the first dielectric layer in the TFT region, where the oxide semiconductor layer in the TFT region has a channel region between a source region and a drain region, forming a second metal layer on the oxide semiconductor layer, the second metal layer in contact with the source region and the drain region, and the second metal layer in contact with a portion of the oxide semiconductor layer in the storage capacitor region, forming a second dielectric layer on the second metal layer and the oxide semiconductor layer in the TFT region, forming a transparent conductive layer over the oxide semiconductor layer in the storage capacitor region, the transparent conductive layer at least partially overlapping with the oxide semiconductor layer in the storage capacitor region, and applying, after any operation subsequent to forming the oxide semiconductor layer, a resistance lowering process to the oxide semiconductor layer in the storage capacitor region so that the oxide semiconductor layer in the storage capacitor region has a lower electrical resistance than the oxide semiconductor layer in the channel region.

In some implementations, applying the resistance lowering process includes exposing at least a portion of the oxide semiconductor layer to ultraviolet light. In some implementations, applying the resistance lowering process includes treating at least a portion of the oxide semiconductor layer with plasma prior to forming the second dielectric layer. In some implementations, the transparent conductive layer is electrically connected to the second metal layer or the oxide semiconductor layer by a transparent via.

Another innovative aspect of the subject matter described in this disclosure can be implemented in a method of manufacturing an apparatus, where the apparatus has a TFT region, a storage capacitor region adjacent to the TFT region, and a common electrode region adjacent to the storage capacitor region. The method includes providing a substrate in the TFT, the storage capacitor, and the common electrode region, forming a first metal layer on the substrate in the TFT region, forming a first dielectric layer on the first metal layer, forming an oxide semiconductor layer in the storage capacitor region and the common electrode region and on the first dielectric layer in the TFT region, where the oxide semiconductor layer in the TFT region has a channel region between a source region and a drain region, forming a second metal layer on the oxide semiconductor layer, the second metal layer in contact with the source region and the drain region, forming a second dielectric layer on the second metal layer and the oxide semiconductor layer in the TFT region, forming a transparent conductive layer over the oxide semiconductor layer in the storage capacitor region, the transparent conductive layer at least partially overlapping with the oxide semiconductor layer in the storage capacitor region, and applying, after any operation subsequent to forming the oxide semiconductor layer, a resistance lowering process to the oxide semiconductor layer in the storage capacitor region and the common electrode region so that the oxide semiconductor layer in the storage capacitor region and the common electrode region has a lower electrical resistance than the oxide semiconductor layer in the TFT region.

In some implementations, applying the resistance lowering process includes exposing at least a portion of the oxide semiconductor layer to ultraviolet light. In some implementations, applying the resistance lowering process includes treating at least a portion of the oxide semiconductor layer with plasma prior to forming the second dielectric layer. In some implementations, the transparent conductive layer is electrically connected to the second metal layer or the oxide semiconductor layer by a transparent via.

Details of one or more implementations of the subject matter described in this disclosure are set forth in the accompanying drawings and the description below. Other features, aspects and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 shows an example of a circuit diagram illustrating a pixel for a display device.

FIG. 4 shows a schematic layout of an example conventional pixel including areas occupied by a TFT and storage capacitor.

FIG. 5A shows a schematic plan view of an example apparatus including a TFT and a storage capacitor, where a transparent via is electrically connected to an oxide semiconductor layer and a common electrode is formed out of the same layer as the source and drain electrodes.

FIG. 5B shows a schematic cross-sectional view of the apparatus of FIG. 5A along lines B1-B1.

FIG. 6A shows a schematic plan view of an example apparatus including a TFT and a storage capacitor, where a transparent via is electrically connected to a drain electrode and a common electrode is formed out of the same layer as the source and drain electrodes.

FIG. 6B shows a schematic cross-sectional view of the apparatus of FIG. 6A along lines B2-B2 according to some implementations.

FIG. 6C shows a schematic cross-sectional view of the apparatus of FIG. 6A along lines B2-B2 according to some other implementations.

FIG. 6D shows a schematic cross-sectional view of the apparatus of FIG. 6A along lines B2-B2 according to some other implementations.

FIG. 7A shows a schematic plan view of an example apparatus including a TFT and a storage capacitor, where a common electrode is formed out of the same layer as an oxide semiconductor layer and a first transparent electrode.

FIG. 7B shows a schematic cross-sectional view of the apparatus of FIG. 7A along lines B3-B3.

FIG. 8A-8G show schematic cross-sectional views illustrating a process for manufacturing an apparatus including a TFT and a storage capacitor, where a transparent via is electrically connected to an oxide semiconductor layer, a common electrode is formed out of the same layer as source and drain electrodes, and ultraviolet (UV) light is used for lowering an electrical resistance of portions of the oxide semiconductor layer.

FIGS. 9A-9D show schematic cross-sectional views illustrating a process for manufacturing an apparatus including a TFT and a storage capacitor, where a transparent via is electrically connected to a drain electrode, a common electrode is formed out of the same layer as source and drain electrodes, and UV light is used for lowering an electrical resistance of portions of the oxide semiconductor layer.

FIGS. 10A-10D show schematic cross-sectional views illustrating a process for manufacturing an apparatus including a TFT and a storage capacitor, where a transparent via is electrically connected to an oxide semiconductor layer, a common electrode is formed out of the same layer as the oxide semiconductor layer and a first transparent electrode, and UV light is used for lowering an electrical resistance of portions of the oxide semiconductor layer.

FIGS. 11A and 11B show schematic cross-sectional views illustrating a process for lowering an electrical resistance of portions of an oxide semiconductor layer using a plasma treatment.

FIGS. 12A and 12B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An apparatus can include a substrate, a common electrode, a TFT, and a storage capacitor adjacent to the TFT. The TFT includes a gate electrode, a first insulating layer, an oxide semiconductor, source and drain electrodes, and a dielectric layer. The storage capacitor includes a first transparent electrode, a second transparent electrode at least partially overlapping the first transparent electrode, and a second insulating layer between the first transparent electrode and the second transparent electrode. The first transparent electrode is formed out of the same layer as the oxide semiconductor and is electrically connected to the common electrode. Thus, the oxide semiconductor is a semiconductor in the region of the TFT and is a conductive electrode (i.e., the first transparent electrode) in the region of the storage capacitor. The common electrode can be electrically connected to the transparent electrode by being formed out of the same layer as the oxide semiconductor and the first transparent electrode, or formed out of the same layer as the source and drain electrodes. In some implementations, the second transparent electrode is electrically connected to the oxide semiconductor or the drain electrode by a transparent via.

Particular implementations of the subject matter described in this disclosure can be implemented to realize one or more of the following potential advantages. Having the first transparent electrode and the oxide semiconductor formed out of the same layer can simplify the manufacturing process and reduce the number of masks in co-fabricating the TFT and storage capacitor. Having the common electrode be formed out of the same layer as the first transparent electrode and oxide semiconductor, or formed out of the same layer as the source and drain electrodes, can further simplify the manufacturing process and further reduce the number of masks in co-fabricating the TFT and storage capacitor. This can reduce manufacturing costs and number of processing steps, as well as the complexity and size of the TFT and storage capacitor. Moreover, the use of transparent materials for the electrodes and the via with respect to the can contribute to a higher definition and higher aperture ratio than conventional display devices.

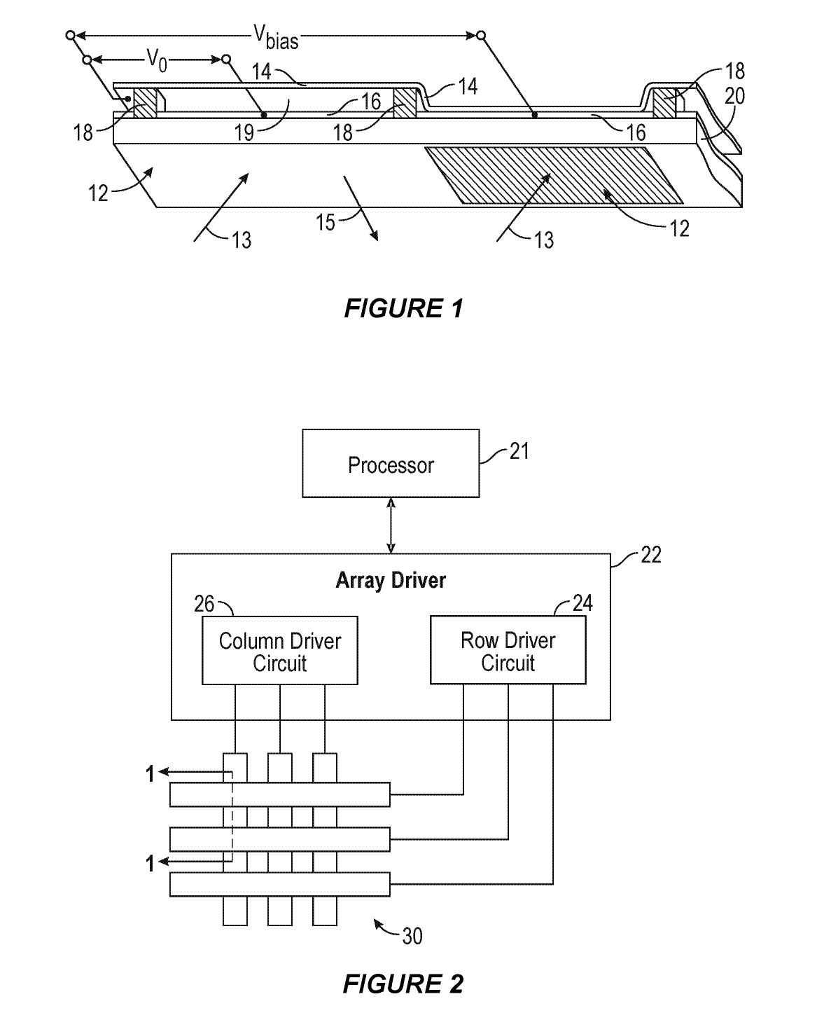

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

Active matrix flat panel displays (AM-FPDs) such as active matrix liquid crystal displays (LCDs), organic light emission displays (OLEDs), and interferometric modulator displays (IMODs), have thin film transistors (TFTs) on transparent substrates. The active matrix flat panel displays can include an array of display elements, which can be referred to as pixels. Some displays can include hundreds, thousands, or millions of pixels arranged in hundreds or thousands of rows and hundreds and thousands of columns. Each pixel can be driven by one or more TFTs. The TFTs may be used to create row and column driver circuits for addressing display elements. Each pixel can include a TFT and a storage capacitor (Cst) to maintain stored charge or voltage during a frame time and/or to speed up device response time. An oxide semiconductor, such as an indium-gallium-zinc-oxide (IGZO) semiconductor, may be used as a material for the active layer of the TFT instead of amorphous silicon or polysilicon for improved mobility and simplified manufacturing.

Pixels in a display device may be arranged in an array such as a two-dimensional grid and addressed by circuits associated with the rows and columns of the array. Row driver circuits may drive the gates of transistor switches that select a particular row to be addressed, column driver circuits may provide data to each pixel of a given row which is addressed, and common driver circuits may provide a bias or fixed voltage to any pixels. The bias or fixed voltage may be applied to one or more rows or columns, a plurality of pixels, or all pixels. The bias may be synchronously updated with a different plane, such as a positive frame or negative frame.

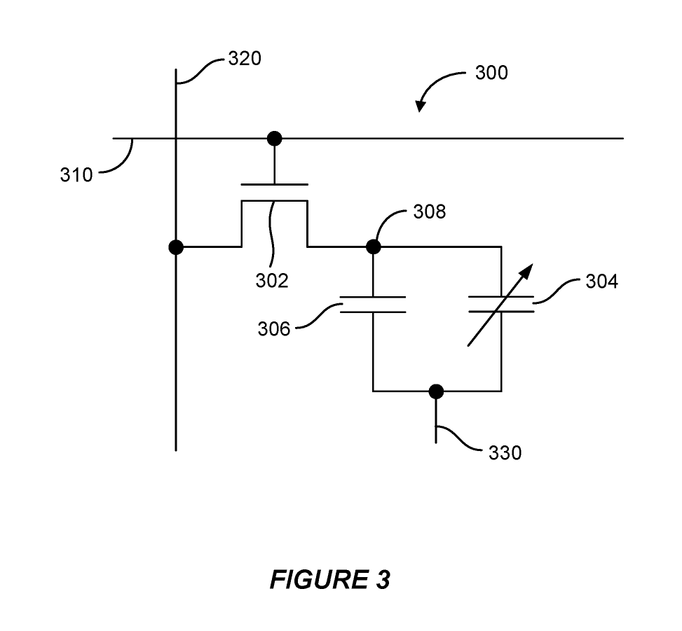

FIG. 3 shows an example of a circuit diagram illustrating a pixel for a display device. In some implementations, the circuit diagram can show a pixel 300 for an active matrix display, where each pixel can be organized in an array to form the display. In FIG. 3, each pixel 300 includes a transistor switch 302, a display element 304, and a storage capacitor 306. The transistor switch 302 can be a TFT. The TFT may be included in row and/or column driver circuits for addressing the display elements 304.

As an example, the pixel 300 may be provided with a row signal from a row electrode 310, a column signal from column electrode 320, and a common signal from a common electrode 330. The implementation of the pixel 300 may include a variety of different designs and is not meant to be limited to the design shown in FIG. 3. The transistor switch 302 can have a gate coupled to the row electrode 310, and column electrode 320 provided to a drain. A description of creating a frame of an image for a pixel with respect to row, common, and column electrodes may be found in U.S. application Ser. No. 13/909,839, titled “Reducing Floating Node Leakage Current with a Feedback Transistor” (Attorney Docket No.: QUALP191/130643), which is hereby incorporated by reference in its entirety and for all purposes.

In one mode of operation, a row driving circuit 310 can turn on one row at a time in an active matrix display device. A column driving circuit 320 can provide data to each pixel 300 of the active matrix display device. When the data is provided from the column driving circuit 320, the data can be stored in a pixel 300 using a storage capacitor 306. As the row driver circuits 310 address each row, the storage capacitor 306 can store the data for the pixel 300 in the previously addressed row. For example, the pixel 300 can continue to display the correct color because the data is stored in the storage capacitor 306. The data may be held at the pixel 300 in a particular row until the row is addressed again, upon which the row of pixels 300 are synchronously updated with a row refresh.

The resolution of a display device can be determined in part by an aperture ratio. The aperture ratio can refer to the combined area of regions that transmit light that contributes to a display operation against the overall display area. With the advance of higher resolution display technology, any decrease in aperture ratio can present an increasingly serious problem. Many conventional display devices have pixels where the gate electrode is formed out of the same layer as one of the electrodes of a storage capacitor, and where the source/drain metal is formed out of the same layer as another one of the electrodes of the storage capacitor. However, if the electrodes of the storage capacitor are formed out of non-transparent material, this reduces the aperture ratio of the display device. To achieve a higher aperture ratio, the area occupied by non-transparent elements of the TFT and the storage capacitor in a pixel should be decreased. Alternatively, such elements can be made transparent themselves so as to achieve a higher aperture ratio. For example, electrodes in a storage capacitor can be made out of indium-tin-oxide (ITO) so that the area occupied by the storage capacitor is transparent. This can lead to higher pixels per inch (PPI) for higher resolution displays.

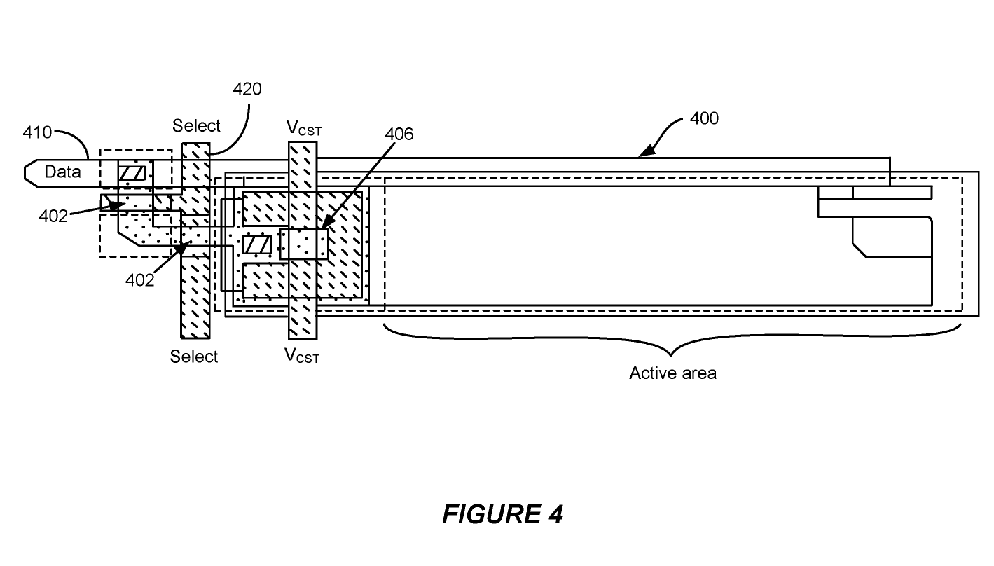

FIG. 4 shows a schematic layout of an example conventional pixel including areas occupied by a TFT and storage capacitor. Display information can be transferred to the pixel's storage capacitors Cst when a voltage is applied to the data bus 410 and the select line 420 is asserted. During the time when select line 420 is asserted, the voltage on the storage capacitor (Vcst) and the voltage on the common electrode (Vcom) (not shown) can be constant. The circuit elements of the pixel 400 shown in FIG. 4, including metal layers, active layers, dielectric layers, and transparent electrode layers can be fabricated on a substrate, such as a substrate glass.

The pixel 400 can include a TFT 402, where the gate electrode of the TFT 402 can be in electrical communication with the select line 420, and the source/drain electrode of the TFT 402 can be in electrical communication with the data bus 410. The pixel 400 can further include a storage capacitor 406 adjacent to the TFT 402. Typically, the storage capacitor 406 may be non-transparent, which reduces the aperture ratio of the pixel 400. Any vias associated with the storage capacitor 406 for electrically connecting the storage capacitor 406 to the TFT 402 may also be non-transparent. However, by making the storage capacitor 406 and vias transparent, the aperture ratio of the pixel 400 can be increased. In addition, the capacitance of the storage capacitor 406 can be increased by increasing the electrode area of the storage capacitor 406 without adversely affecting the aperture ratio. Thus, the display quality is not degraded by an increase in the pixel's capacitance.

Transparent electrodes can be formed out of transparent conductive materials, including but not limited to indium-tin-oxide (ITO), indium-zinc-oxide (IZO), and aluminum-doped zinc oxide (AZO). Deposition and patterning of such transparent conductive materials can add to the complexity and manufacturing costs in fabricating a storage capacitor and TFT associated with a display element. However, using an oxide semiconductor layer of a TFT as the same layer as one of the transparent electrodes of a storage capacitor can reduce the number of masks in the manufacturing process. This can simplify fabrication and reduce manufacturing costs. The oxide semiconductor layer can be transparent and locally treated by a resistance lowering process so that portions of the oxide semiconductor layer can become conductive.

In addition, a common electrode for applying a common voltage to a plurality of pixels can be electrically connected to the transparent electrode formed by the resistance lowering process. In some implementations, the common electrode can be formed out of the same metal layer as the source and drain electrodes of the TFT, or out of the same layer as the oxide semiconductor and the transparent electrode formed by the resistance lowering process. This can further reduce the number of masks in the manufacturing process, which can further simplify fabrication and reduce manufacturing costs.

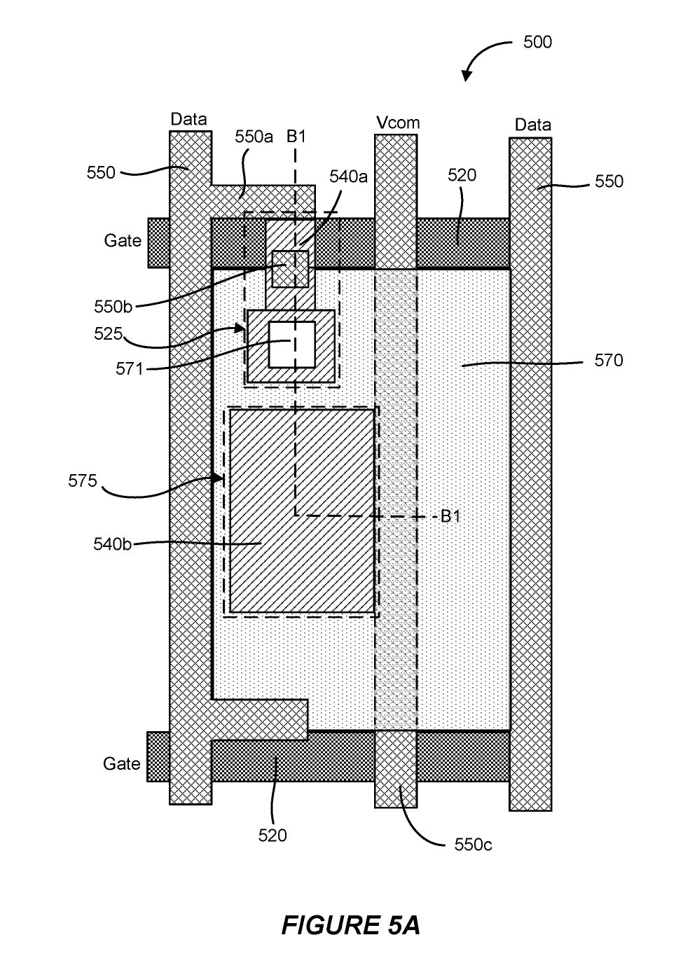

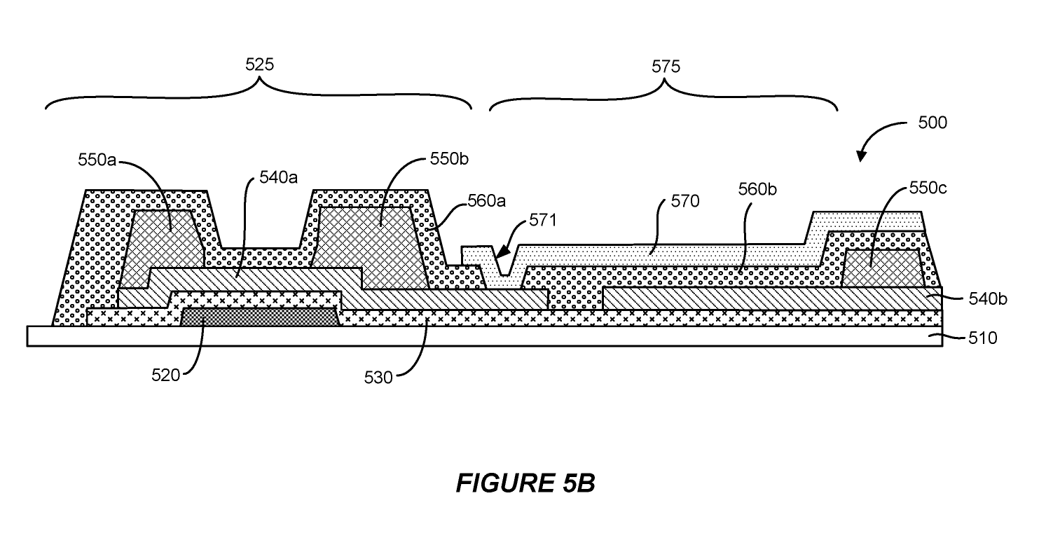

FIG. 5A shows a schematic plan view of an example apparatus including a TFT and a storage capacitor, where a transparent via is electrically connected to an oxide semiconductor layer and a common electrode is formed out of the same layer as the source and drain electrodes. FIG. 5B shows a schematic cross-sectional view of the apparatus of FIG. 5A along lines B1-B1. In some implementations, an apparatus 500 is a pixel or part of a pixel in a display device.

The apparatus 500 includes a substrate 510. The substrate 510 can include any suitable substrate material, such as a glass, plastic, or semiconducting material. In some implementations, the substrate 510 can be a transparent substrate, such as a glass substrate (sometimes referred to as a glass plate or panel). The glass substrate may be or include, for example, a borosilicate glass, a soda lime glass, quartz, Pyrex®, or other suitable glass material. In some implementations, the substrate 510 can be a plastic substrate, such as a polyethylene terephthalate (PET) or polyethylene naphthalate (PEN) substrate. Other possible materials for the substrate 510 can include polyether sulfone (PES), acrylic resin, and polyimide resin. In some implementations, the substrate 510 can be a semiconducting substrate, such as a silicon substrate. In some implementations, the substrate 510 can have dimensions of a few microns to hundreds of microns.

The substrate 510 can be substantially transparent, where substantial transparency as used herein can be defined as transmittance of visible light of about 70% or more, such as about 80% or more or about 90% or more. The substrate 510 can be made of a substantially transparent material, such as glass or plastic. In addition or in the alternative, the substrate 510 can be substantially transparent to ultraviolet (UV) light.

The apparatus 500 further includes a TFT 525 and a storage capacitor 575 adjacent to the TFT. In FIG. 5B, the TFT 525 is shown on the left-hand side whereas the storage capacitor 575 is shown on the right-hand side. The TFT 525 includes a gate electrode 520, a gate insulating layer 530, an oxide semiconductor layer 540a, a source electrode 550a, and a drain electrode 550b. The gate electrode 520 can be disposed on the substrate 510. In some implementations, the gate electrode 520 can be disposed on a buffer layer, where the buffer layer can be on the substrate 510 and provide an insulation surface upon which the gate electrode 520 is formed. A gate insulating layer 530 and an oxide semiconductor layer 540a can be disposed over the gate electrode 520, where the gate insulating layer 530 is between the gate electrode 520 and the oxide semiconductor layer 540a. The oxide semiconductor layer 540a can include a source region, a drain region, and a channel region, where the channel region is between the source region and the drain region. The oxide semiconductor layer 540a can be aligned with the gate electrode 520. A source electrode 550a can be contacting the source region of the oxide semiconductor layer 540a and a drain electrode 550b can be contacting the drain region of the oxide semiconductor layer 540a. In FIG. 5B, for example, the source electrode 550a is disposed on the source region and the drain electrode 550b is disposed on the drain region. In addition, the TFT 525 can include a dielectric layer 560a over the channel region of the oxide semiconductor layer 540a. The dielectric layer 560a may contact the channel region of the oxide semiconductor layer 540a. The dielectric layer 560a may be over the source and drain electrodes 550a, 550b. It will be understood that the TFT 525 can have other designs known in the art, including top gate and bottom gate TFTs, planar and staggered TFTs, etc.

The gate electrode 520 can include an electrically conductive material, such as a metal. For example, the gate electrode 520 can include titanium (Ti), molybdenum (Mo), tantalum (Ta), tungsten (W), nickel (Ni), gold (Au), copper (Cu), aluminum (Al), chromium (Cr), neodymium (Nd), or any combination of such elements. In some implementations, the gate electrode 520 includes two or more sub-layers of different metals arranged in a stacked structure. In some implementations, the gate electrode 520 can have a thickness between about 50 nm and about 600 nm, or between about 100 nm and about 250 nm. In some implementations, the gate electrode 520 may be substantially non-transparent to UV and visible light. As shown in FIG. 5A, the gate electrode 520 can be electrically connected to a gate line of the apparatus 500, where the gate line runs perpendicularly to a data line 550 of the apparatus 500.

The gate insulating layer 530 can include any appropriate insulating material, such as a dielectric material. For example, the gate insulating layer 530 can include silicon oxide (SiO₂), aluminum oxide (Al₂O₃), hafnium oxide (HfO₂), titanium oxide (TiO₂), silicon oxynitride (SiON), or silicon nitride (SiN). In some implementations, the gate insulating layer 530 includes two or more sub-layers of different dielectric materials arranged in a stacked structure. In some implementations, the gate insulating layer 530 can have a thickness between about 50 nm and about 600 nm, or between about 100 nm and about 250 nm.

The oxide semiconductor layer 540a can include any appropriate oxide semiconducting materials, such as indium (In)-containing, zinc (Zn)-containing, tin (Sn)-containing, hafnium (Hf)-containing, and gallium (Ga)-containing oxide semiconducting materials. Examples include indium-gallium-zinc-oxide (IGZO), indium-zinc-tin-oxide (IZTO), zinc oxide (ZnO), indium-zinc-oxide (IZO), indium oxide (InO), and tin oxide (SnO). In some implementations, the oxide semiconductor layer 540a includes IGZO. The oxide semiconductor layer 540a can be amorphous or crystalline. In some implementations, the oxide semiconductor layer 540a can have a thickness between about 10 nm and about 100 nm. Moreover, the oxide semiconductor layer 540a can be made of a material that is substantially transparent to visible light.

The source and drain electrodes 550a, 550b can include an electrically conductive material, such as a metal. Examples include Ti, Mo, Ta, W, Ni, Au, Cu, Al, Cr, Nd, and alloys containing such elements. In some implementations, the source and drain electrodes 550a and 550b include a transparent metal oxide, such as indium-tin-oxide (ITO). In some implementations, the source and drain electrodes 550a, 550b include two or more sub-layers of different metals arranged in a stacked structure. In some implementations, the source and drain electrodes 550a, 550b have a thickness between about 50 nm and about 600 nm, or between about 100 nm and about 250 nm. As shown in FIG. 5A, the source and drain electrodes 550a, 550b can be electrically connected to the data line 550, where the data line runs 550 perpendicularly to the gate line of the apparatus 500.

The dielectric layer 560a can include any appropriate insulating material. Examples include SiO₂, Al₂O₃, HfO₂, TiO₂, SiON, and SiN. The dielectric layer 560a can serve as a protective layer or passivation layer for the TFT 525. If the dielectric layer 560a is made of an oxide, it is possible for the dielectric layer 560a to prevent oxygen deficiencies of the oxide semiconductor layer 540a from deteriorating the semiconductor properties of the oxide semiconductor layer 540a. In some implementations, the dielectric layer 560a can have a thickness between about 50 nm and about 300 nm, or between about 100 nm and about 200 nm.

The apparatus 500 includes a storage capacitor 575 positioned adjacent to the TFT 525. The storage capacitor 575 includes a first transparent electrode 540b over the substrate 510, a second transparent electrode 570 over the first transparent electrode 540b and at least partially overlapping with the first transparent electrode 540b, and an insulating layer 560b between the first transparent electrode 540b and the second transparent electrode 570. As used herein, the term “overlap” indicates that two structures overlap one another when viewed from a viewpoint located along an axis that is normal or substantially normal to major surfaces of one or both structures. In some implementations, the area of overlap can define a capacitance Cst of the storage capacitor 575. In some implementations, the capacitance Cst of the storage capacitor 575 can be increased by reducing the thickness of the insulating layer 560b and/or by increasing the area of the electrodes 540b, 570. The insulating layer 560b can be formed out of the same layer as the dielectric layer 560a. In addition, the second transparent electrode 570 can be electrically connected to the oxide semiconductor layer 540a of the TFT 525 by a transparent via 571. Rather than electrically connecting the first transparent electrode 540b or the second transparent electrode 570 directly with the drain electrode 550b, the second transparent electrode 570 can electrically connect with the oxide semiconductor layer 540a by the transparent via 571 in such implementations represented by FIGS. 5A and 5B. The transparent via 571 can contact the oxide semiconductor layer 540a through a via hole formed in the dielectric layer 560a.

In implementations where the storage capacitor 575 is positioned in a viewable area of a display device, the storage capacitor 575 can be substantially transparent to visible light. Accordingly, each of the electrodes 540b, 570 and the insulating layer 560b can be substantially transparent to visible light. This can increase the aperture ratio of a display device.

The first transparent electrode 540b can have a substantially similar thickness and composition as the oxide semiconductor layer 540a. Accordingly, the first transparent electrode 540b can include In-containing, Zn-containing, Sn-containing, Hf-containing, and Ga-containing oxide materials, such as IGZO, IZTO, ZnO, IZO, InO, or SnO, and can have a thickness between about 10 nm and about 100 nm. A substantially similar thickness can refer to a thickness variation between two layers that is about 5% or less, or about 3% or less. A substantially similar composition can refer to an atomic percent variation of elements between two layers that is about 5% or less, or about 3% or less. In fact, the first transparent electrode 540b can be formed out of the same layer as the oxide semiconductor layer 540a. This means that the first transparent electrode 540b can share a common thin film layer with the oxide semiconductor layer 540a. This can reduce the number of masks and manufacturing steps in fabricating the TFT 525 and the storage capacitor 575.

The first transparent electrode 540b can have a lower electrical resistance than the oxide semiconductor layer 540a in the channel region. In some implementations, the first transparent electrode 540b can be a transparent conductive oxide while the oxide semiconductor layer 540a in the channel region can be a transparent semiconducting oxide. The first transparent electrode 540b can have a lower electrical resistance than the oxide semiconductor layer 540a in the channel region by applying a resistance lowering process. Specifically, a portion of the common thin film layer shared by the first transparent electrode 540b and the oxide semiconductor layer 540a, where the common thin film layer can be a common oxide semiconductor thin film, can be subjected to a localized resistance lowering process. Resistance lowering processes, which can include exposure to UV light or plasma treatment, are discussed in more detail below. Nonetheless, a portion of the common oxide semiconductor thin film, such as a portion not masked by the gate electrode 520 or a portion extending outside the channel region of the oxide semiconductor layer 540a, can be transformed to a transparent conductive oxide by the resistance lowering process. In some implementations, the drain region of the oxide semiconductor layer 540a has a lower electrical resistance than the channel region of the oxide semiconductor layer 540a.

The second transparent electrode 570 can include a transparent and electrically conductive material. In some implementations, the second transparent electrode 570 can include at least one of indium-tin-oxide (ITO), indium-zinc-oxide (IZO), and aluminum-doped zinc oxide (AZO). In some implementations, the second transparent electrode 570 can have a thickness between about 10 nm and about 300 nm, or between about 50 nm and about 200 nm.

The apparatus 500 can further include a common electrode 550c that is electrically connected to the first transparent electrode 540b of the storage capacitor 575. As shown in FIG. 5A, the common electrode 550c is formed along the line indicated by Vcom and parallel to the data line 550. As shown in FIG. 5B, the common electrode 550c is formed on the first transparent electrode 540b. Rather than electrically connecting the first transparent electrode 540b directly with the drain electrode 550b, or with the source electrode 550a for that matter, the first transparent electrode 540b is directly electrically connected with the common electrode 550c. The common electrode 550c can have a substantially similar thickness and composition as the source and drain electrodes 550a, 550b. Accordingly, the common electrode 550c can include any suitable electrically conductive material, such as Ti, Mo, Ta, W, Ni, Au, Cu, Al, Cr, Nd, and alloys containing such elements, and can have a thickness between about 50 nm and about 600 nm. In fact, the common electrode 550c can be formed out of the same layer as the source and drain electrodes 550a, 550b. This means that the common electrode 550c can share a common thin film layer with the source and drain electrodes 550a, 550b. This can reduce the number of masks and manufacturing steps in fabricating the common electrode 550c, the storage capacitor 575, and the TFT 525. This also enables the common electrode 550c to be formed out of a material of low electrical resistance for improved device performance.

A common voltage (Vcom) may be applied to the common electrode 550c. In a display device, Vcom is applied as a fixed voltage from the common electrode 550c to all display elements (e.g., pixels), a plurality of display elements, or any display element. Accordingly, a display device can include an apparatus 500 and a plurality of display elements, where the common electrode 550c is configured to apply Vcom to each of the plurality of display elements. Vcom may be applied so that a reference voltage can be applied to the plurality of display elements. For example, in a positive plane the reference voltage for Vcom can be 0 V, and in a negative plane the reference voltage for Vcom can be 4-7 V. In some implementations, such as in LCD applications, a voltage according to display content for a pixel is applied to a pixel electrode, and Vcom is applied to the common electrode 550c that serves as a counter electrode to the pixel electrode. In some implementations, the common electrode 550c may be a layer that is outside the viewable area of the display. In some implementations, the common electrode 550c may be formed continuously and through all of the pixels of a display device. Incorporating a common electrode 550c through the pixels of a display device may be useful in large-sized panels of the display device.

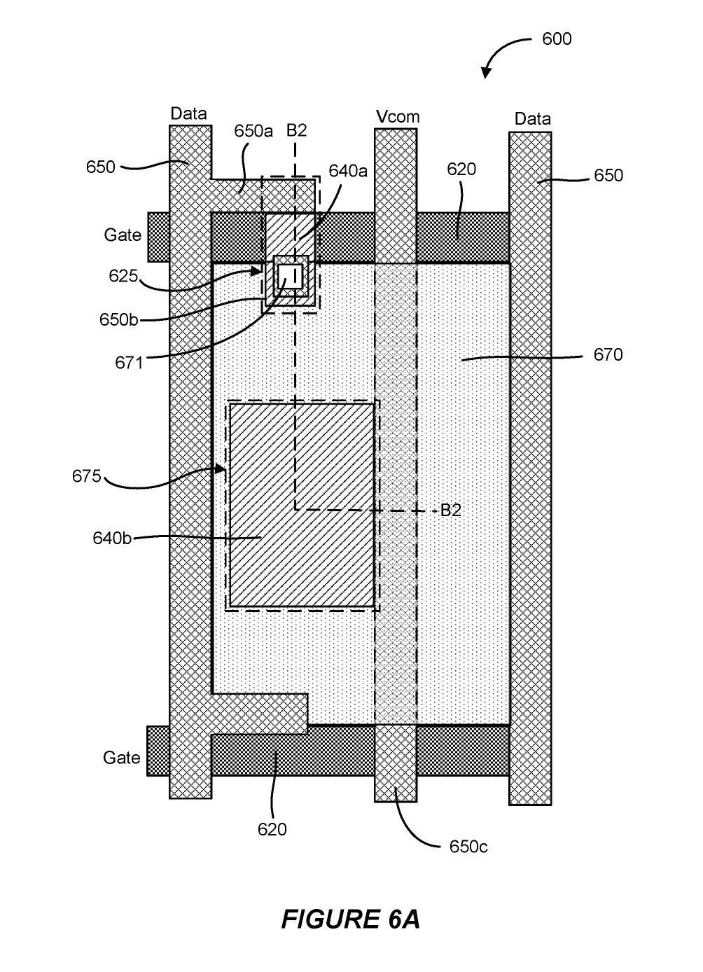

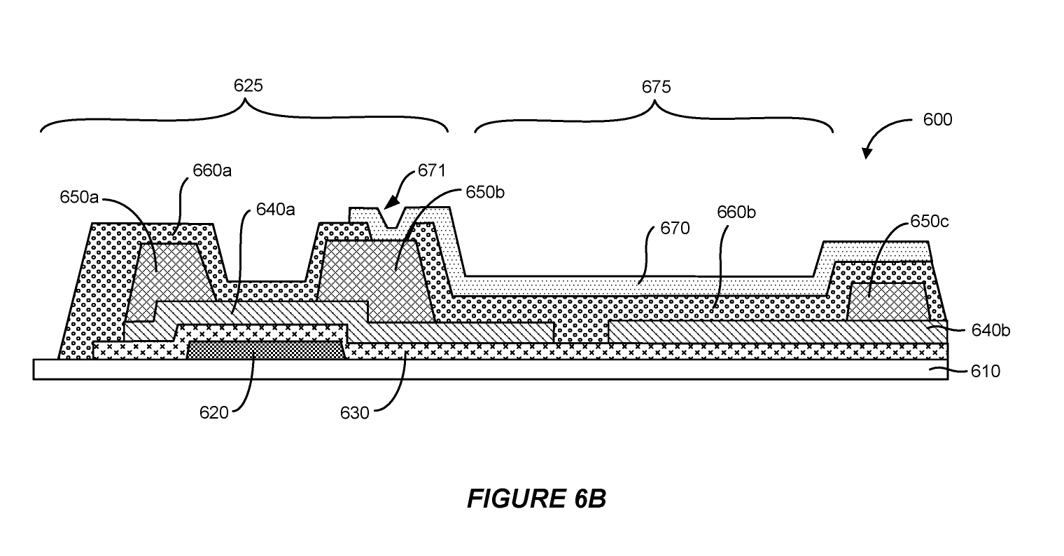

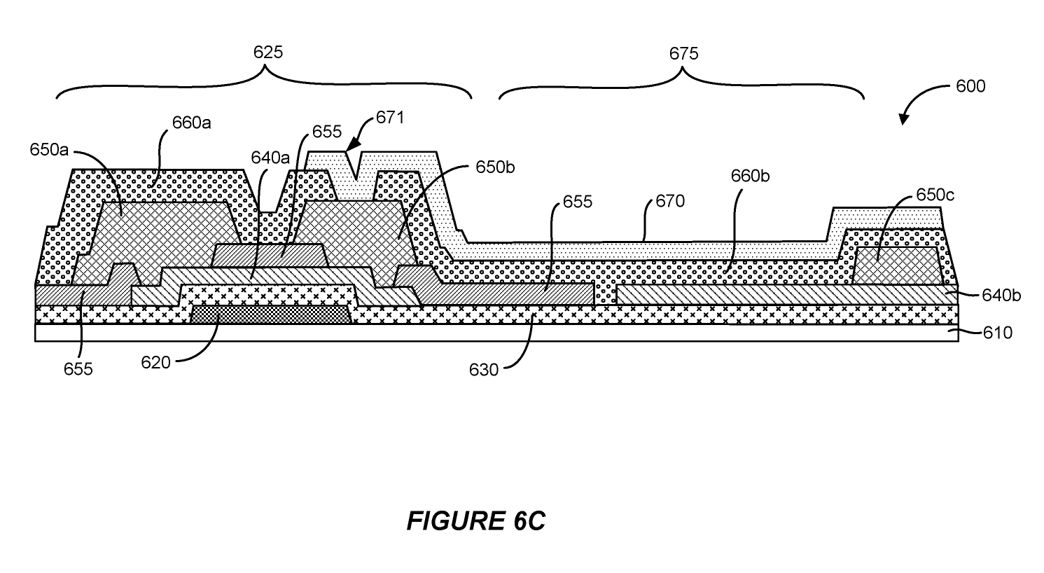

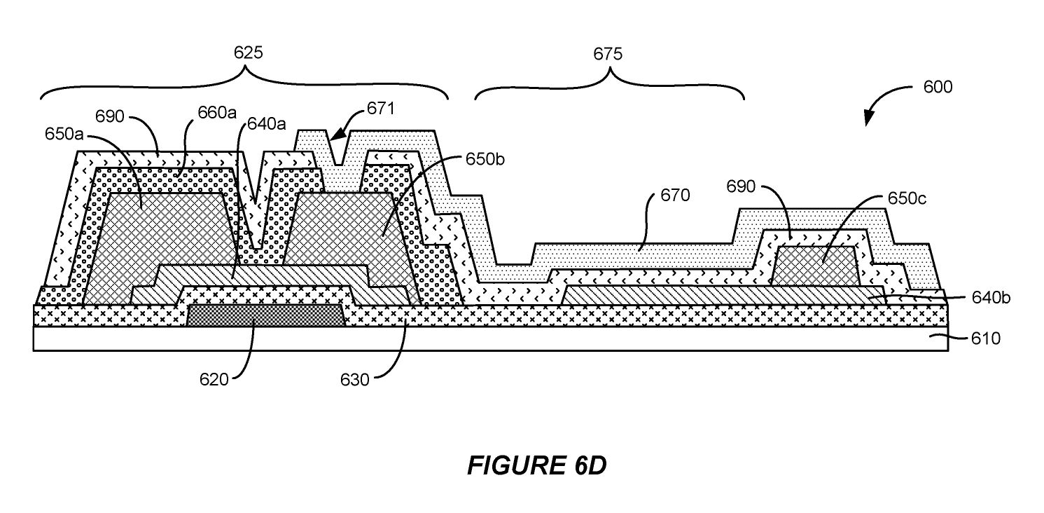

FIG. 6A shows a schematic plan view of an example apparatus including a TFT and a storage capacitor, where a transparent via is electrically connected to a drain electrode and a common electrode is formed out of the same layer as the source and drain electrodes. FIG. 6B shows a schematic cross-sectional view of the apparatus of FIG. 6A along lines B2-B2 according to some implementations. FIG. 6C shows a schematic cross-sectional view of the apparatus of FIG. 6A along lines B2-B2 according to some other implementations. FIG. 6D shows a schematic cross-sectional view of the apparatus of FIG. 6A along lines B2-B2 according to some other implementations. In some implementations, an apparatus 600 is a pixel or part of a pixel of a display device.

The apparatus 600 includes a substrate 610, a TFT 625, a storage capacitor 675 adjacent to the TFT 625, and a common electrode 650c. Aspects of the apparatus 600 in FIGS. 6A, 6B, 6C, and 6D may be similar to aspects of the apparatus 500 in FIGS. 5A and 5B. Accordingly, the discussion regarding the apparatus 500, the substrate 510, the TFT 525, the storage capacitor 575, and the common electrode 550c can equally apply to the apparatus 600, the substrate 610, the TFT 625, and the common electrode 650c, except that the second transparent electrode 670 of the storage capacitor 675 is electrically connected to the drain electrode 650b instead of the oxide semiconductor 640a. Having the second transparent electrode 670 electrically connected to the drain electrode 650b can provide a higher capacitance for the storage capacitor 675. As shown in FIGS. 6B, 6C, and 6D, the second transparent electrode 670 is electrically connected to the drain electrode 650b by a transparent via 671.

The substrate 510 in FIGS. 5A and 5B may be similar to the substrate 610 in FIGS. 6A, 6B, 6C, and 6D. The common electrode 550c in FIGS. 5A and 5B may be similar to the common electrode 650c in FIGS. 6A, 6B, 6C, and 6D. Also, like the TFT 525 in FIGS. 5A and 5B, the TFT 625 in FIGS. 6A, 6B, 6C, and 6D includes a gate electrode 620, a gate insulating layer 630, an oxide semiconductor layer 640a, source and drain electrodes 650a, 650b, and a dielectric layer 660a. And like the storage capacitor 575 in FIGS. 5A and 5B, the storage capacitor 675 in FIGS. 6A, 6B, 6C, and 6D includes at least a first transparent electrode 640b and a second transparent electrode 670. However, the second transparent electrode 670 is electrically connected to the drain electrode 650b of the TFT 625 by a transparent via 671. Rather than electrically connecting the first transparent electrode 640b directly to the drain electrode 650b, or the second transparent electrode 670 directly to the oxide semiconductor layer 640a as shown in FIGS. 5A and 5B, the second transparent electrode 670 can electrically connect to the drain electrode 650b by the transparent via 671. The transparent via 671 can contact the drain electrode 650b through a via hole formed in the dielectric layer 660.

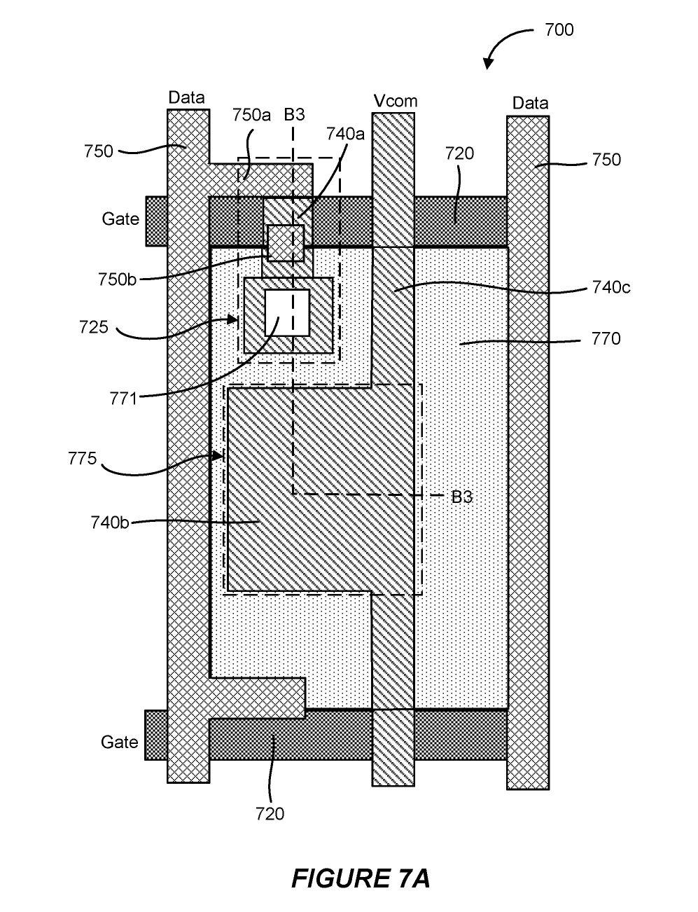

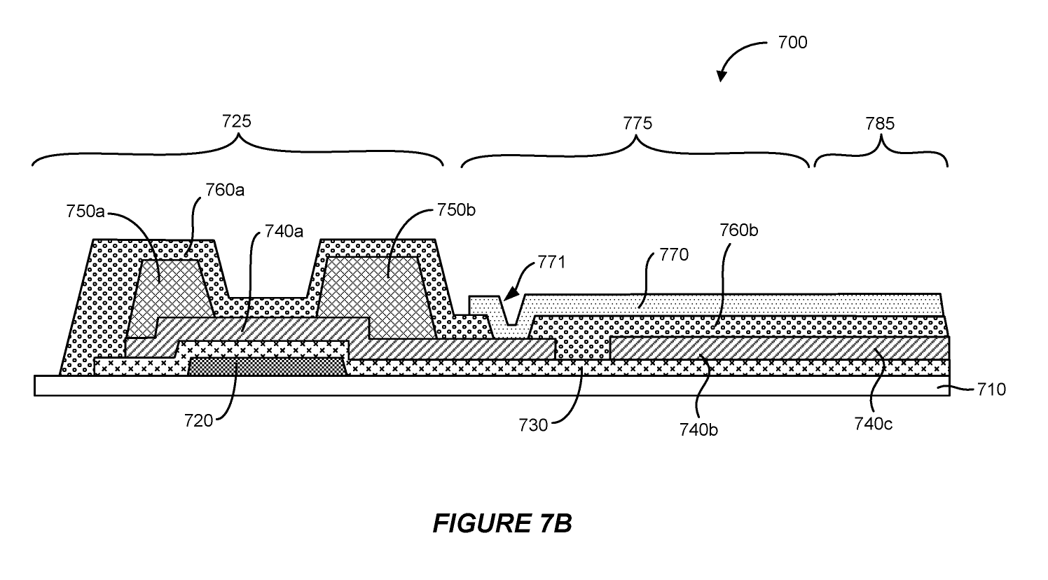

In addition, the apparatus 600 in FIG. 6C includes an etch stop layer 655, whereas the apparatus 600 in FIG. 6B does not include an etch stop layer 655. The etch stop layer 655 can be formed on the oxide semiconductor layer 640a to protect the oxide semiconductor layer 640a against over-etching. The etch stop layer 655 can be between the oxide semiconductor layer 640a and the dielectric layer 660. In some implementations, the etch stop layer 655 is on the channel region of the oxide semiconductor layer 640a, and can be between the oxide semiconductor layer 640a and the source and drain electrodes 650a, 650b. In some implementations, the etch stop layer 655 is also on the gate insulating layer 630, where the etch stop layer 655 can be between the gate insulating layer 630 and the dielectric layer 660a. The etch stop layer 655 can include any appropriate insulating material, such as a dielectric material. For example, the etch stop layer can include can include any appropriate insulating material. Examples include SiO₂, Al₂O₃, HfO₂, TiO₂, SiON, and SiN. The etch stop layer 655 can serve to protect the TFT 625 in the apparatus 600. The etch stop layer 655 can serve to protect etch processing steps of underlying layers, such as the oxide semiconductor layer 640a. In some implementations, the etch stop layer 655 can have a thickness between about 50 nm and about 500 nm. While the etch stop layer 655 is shown in the apparatus 600, it is understood that the etch stop layer 655 can also be incorporated in other implementations, including the apparatus 500 in FIGS. 5A and 5B and the apparatus 700 in FIGS. 7A and 7B. Specifically, the etch stop layer 655 can be incorporated in implementations that do not form an apparatus using a back channel etch method.

Furthermore, whereas the storage capacitor 675 in FIGS. 6A, 6B, 6C, and 6D can include at least a first transparent electrode 640b and a second transparent electrode 670 like the storage capacitor 575 in FIGS. 5A and 5B, the storage capacitor 675 may not necessarily use the same layer as the dielectric layer 660a. In FIG. 6B, the storage capacitor 675 includes an insulating layer 660b, which is formed out of the same layer as the dielectric layer 660a. In FIG. 6D, the storage capacitor 675 includes an insulating layer 690, which is a separate layer from the dielectric layer 660a. The insulating layer 690 can be between the first transparent electrode 640b and the second transparent electrode 670. While the insulating layer 690 is shown in the apparatus 600, it is understood that the insulating layer 690 can also be incorporated in other implementations, including the apparatus 500 in FIGS. 5A and 5B and the apparatus 700 in FIGS. 7A and 7B. In some implementations, the apparatus 600 in FIG. 6D can include the insulating layer 690 over the dielectric layer 660a, where the insulating layer 690 is part of both the TFT 625 and the storage capacitor 675, and the dielectric layer 660a is not part of the storage capacitor 675. In some implementations, the apparatus 600 can include the insulating layer 690 over the dielectric layer 660a, but the insulating layer 690 is not part of the storage capacitor 675. Instead, the dielectric layer 660a is between the first transparent electrode 640b and the second transparent electrode 670. In some implementations, the apparatus 600 can include the insulating layer 690 over the dielectric layer 660a, where both the insulating layer 690 and the dielectric layer 660a are part of the TFT 625 and the storage capacitor 675. Also, though the apparatus 600 in FIG. 6C does not show the etch stop layer 655 extending in between the first transparent electrode 640b and the second transparent electrode 670, some implementations of the apparatus 600 can include the etch stop layer 655 as the insulating layer between the first transparent electrode 640b and the second transparent electrode 670.

FIG. 7A shows a schematic plan view of an example apparatus including a TFT and a storage capacitor, where a common electrode is formed out of the same layer as an oxide semiconductor layer and a first transparent electrode. FIG. 7B shows a schematic cross-sectional view of the apparatus of FIG. 7A along lines B3-B3. In some implementations, an apparatus 700 is a pixel or part of a pixel of a display device.

The apparatus 700 includes a substrate 710, a TFT 725, a storage capacitor 775 adjacent to the TFT 725, and a common electrode 740c. Aspects of the apparatus 700 in FIGS. 7A and 7B may be similar to aspects of the apparatus 500 in FIGS. 5A and 5B. Accordingly, the discussion regarding the apparatus 500, the substrate 510, the TFT 525, the storage capacitor 575, and the common electrode 550c can equally apply to the apparatus 700, the substrate 710, the TFT 725, and the common electrode 740c, except that the common electrode 740c is substantially similar in thickness and composition as the oxide semiconductor layer 740a. Having the common electrode 740c be substantially similar in thickness and composition as the oxide semiconductor layer 740a can increase aperture ratio and achieve higher PPI in display applications. In some implementations, the common electrode 740c has a substantially similar thickness and composition as the first transparent electrode 740b. The common electrode 740c can include In-containing, Zn-containing, Sn-containing, Hf-containing, and Ga-containing oxide materials, such as IGZO, IZTO, ZnO, IZO, InO, or SnO, and can have a thickness between about 10 nm and about 100 nm. In some implementations, the common electrode 740c can be formed out of the same layer as the oxide semiconductor layer 740a and the first transparent electrode 740b.

The substrate 510 in FIGS. 5A and 5B may be similar to the substrate 710 in FIGS. 7A and 7B. Also, like the TFT 525 in FIGS. 5A and 5B, the TFT 725 in FIGS. 7A and 7B includes a gate electrode 720, a gate insulating layer 730, an oxide semiconductor layer 740a, source and drain electrodes 750a, 750b, and a dielectric layer 760a. And like the storage capacitor 575 in FIGS. 5A and 5B, the storage capacitor 775 in FIGS. 7A and 7B includes a first transparent electrode 740b, an insulating layer 760b, and a second transparent electrode 770, where the second transparent electrode 770 can be electrically connected to the oxide semiconductor layer 740a by a transparent via 771. The dielectric layer 760a can share a common thin film layer with the insulating layer 760b. The oxide semiconductor layer 740a can share a common thin film layer with the first transparent electrode 740b. However, the common electrode 740c can also share the common thin film layer with the oxide semiconductor layer 740a and the first transparent electrode 740b. Both the first transparent electrode 740b and the common electrode 740c can have a lower electrical resistance than the oxide semiconductor layer 740a in the channel region by applying a resistance lowering process. A portion of the common thin film layer made of a transparent oxide semiconducting material can be transformed to a transparent conductive oxide by the resistance lowering process, where such a portion includes the first transparent electrode 740b and the common electrode 740c. Rather than having the common electrode 740c formed out of the same layer as the source and drain electrodes 750a, 750b, the common electrode 740c can be formed out of the same layer as the oxide semiconductor layer 740a and the first transparent electrode 740b. The common electrode 740c can be formed in a region 785 outside of where the second transparent electrode 770 overlaps with the first transparent electrode 740b.

Though not illustrated in FIGS. 7A and 7B, in some implementations, the apparatus 700 can have the second transparent electrode 770 electrically connected to the drain electrode 750b rather than electrically connected to the oxide semiconductor layer 740a. The second transparent electrode 770 can be electrically connected to the drain electrode 750b by the transparent via 771. Though not illustrated in FIGS. 7A and 7B, in some implementations, the apparatus 700 can further include an etch stop layer, such as an etch stop layer 655 in FIG. 6C, and/or an insulating layer 690 in FIG. 6D.

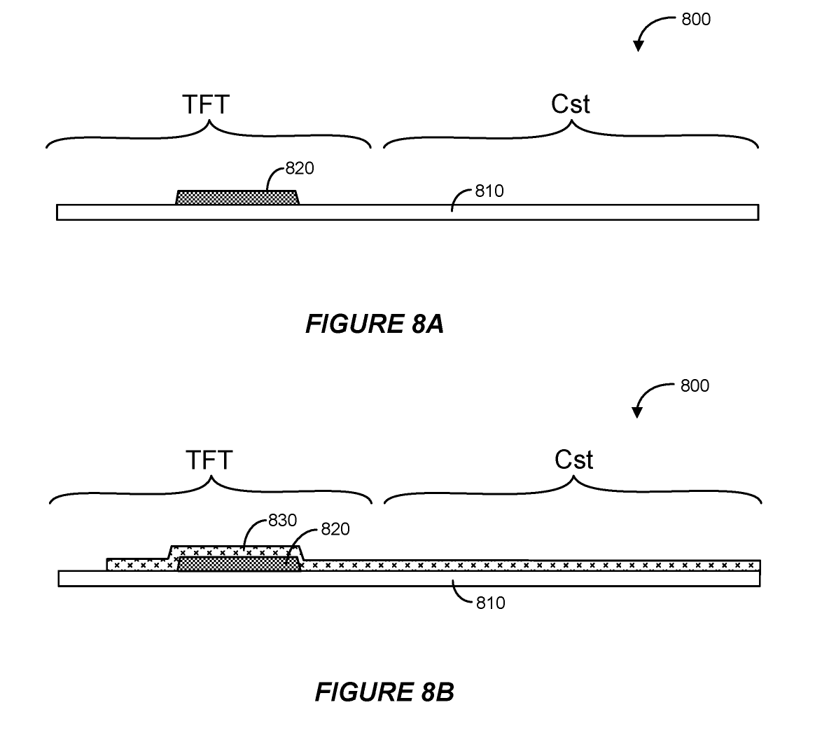

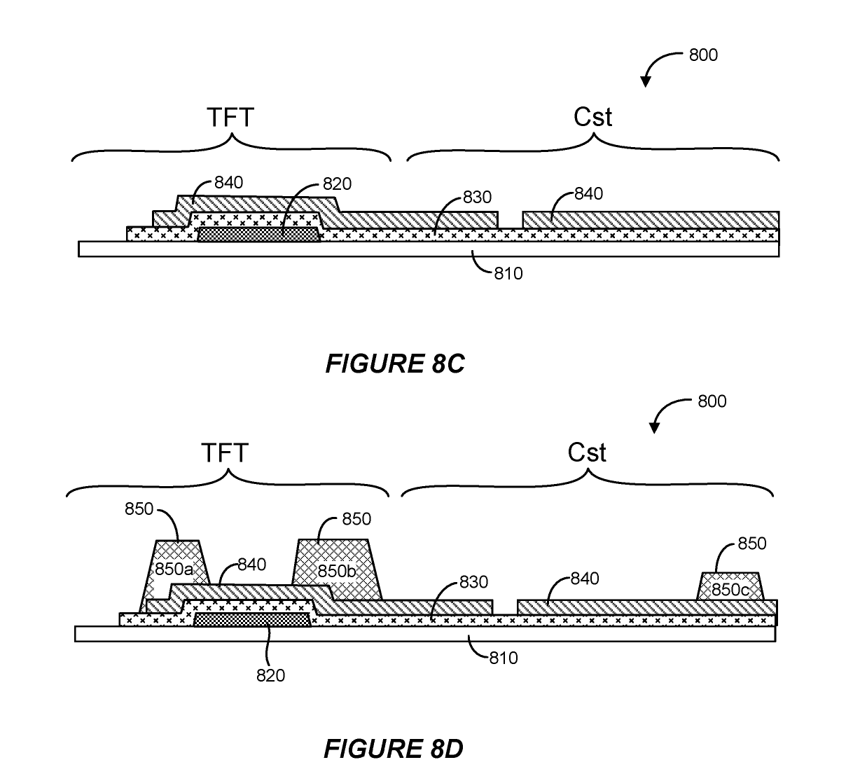

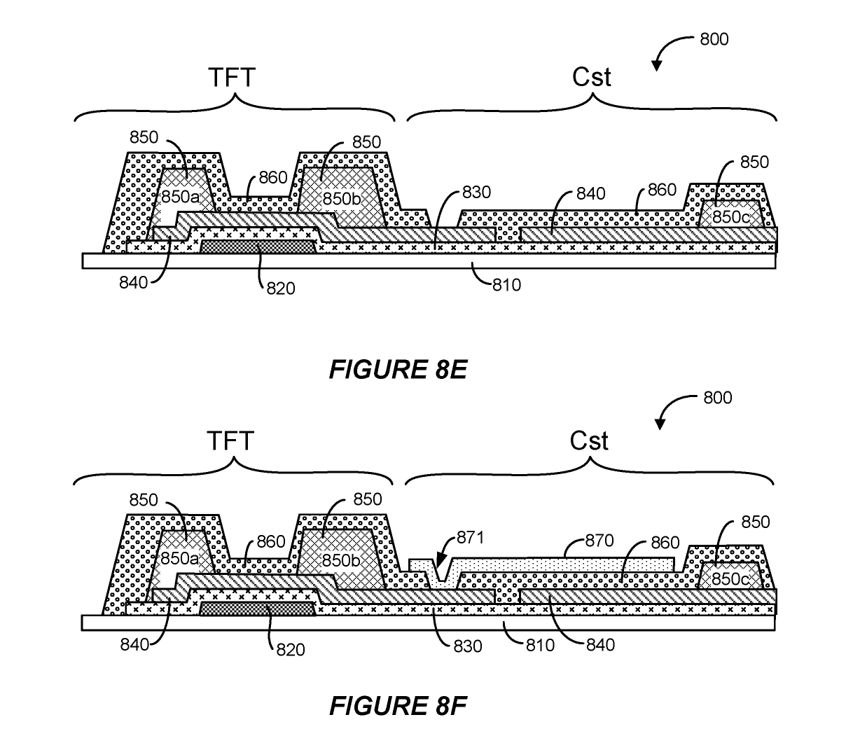

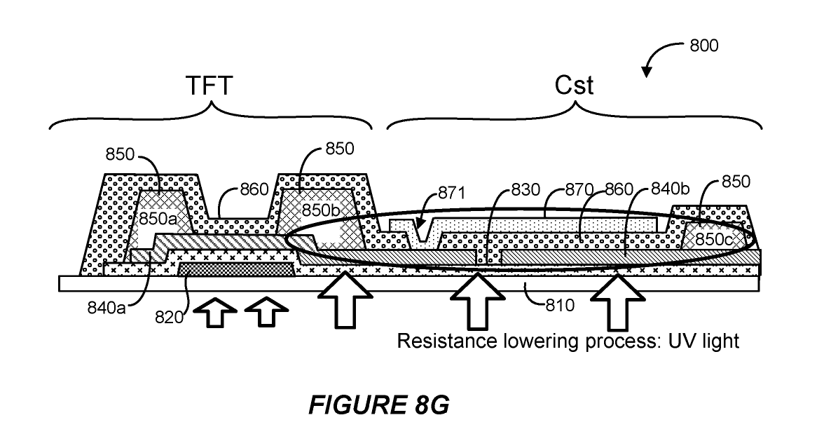

FIG. 8A-8G show schematic cross-sectional views illustrating a process for manufacturing an apparatus including a TFT and a storage capacitor, where a transparent via is electrically connected to an oxide semiconductor layer, a common electrode is formed out of the same layer as source and drain electrodes, and ultraviolet (UV) light is used for lowering an electrical resistance of portions of the oxide semiconductor layer. Accordingly, FIGS. 8A-8G illustrate a process for manufacturing the apparatus 500 shown in FIGS. 5A and 5B. The process for manufacturing the apparatus may be performed in a different order or with different, fewer, or additional operations. In some implementations, the process in FIGS. 8A-8G may illustrate a process for manufacturing a display element (e.g., pixel) for a display device.

In FIGS. 8A-8G, the apparatus 800 can have a TFT region (labeled “TFT”) and a storage capacitor region (labeled “Cst”) adjacent to the TFT region. In FIG. 8A, a substrate 810 is provided in the TFT and the storage capacitor region, and a first metal layer 820 is formed on the substrate 810 in the TFT region. The substrate 810 can include any suitable substrate material, such as glass, plastic, or semiconducting material. The substrate 810 can be substantially transparent to ultraviolet and visible light. In some implementations, the substrate 810 can be a glass, PET, or PEN substrate. In some implementations, the substrate 810 can have a thickness in the range of about few microns to several hundreds of microns. The first metal layer 820 may be formed in the TFT region using any number of deposition, masking, and/or etching steps. The first metal layer 820 may be deposited using deposition processes as known by a person having ordinary skill in the art, including physical vapor deposition (PVD) processes, chemical vapor deposition (CVD) processes, and atomic layer deposition (ALD) processes. PVD processes include thermal evaporation deposition, sputter deposition and pulsed laser deposition (PLD). The first metal layer 820 can include at least one of Ti, Mo, Ta, W, Ni, Au, Cu, Al, Cr, and Nd, and can have a thickness between about 50 nm and about 600 nm. The first metal layer 820 may be patterned (mask1) and etched using suitable techniques known in the art, such as a dry (e.g., plasma) etching process or a wet chemical etching process. The first metal layer 820 can serve as a gate electrode for a TFT.

In FIG. 8B, a first dielectric layer 830 is formed on the first metal layer 820. In some implementations as shown in FIG. 8B, the first dielectric layer 830 is formed across the TFT region and the storage capacitor region. In other implementations, the first dielectric layer 830 is formed in the TFT region only. Forming the first dielectric layer 830 may include steps of depositing, masking, and/or etching. The first dielectric layer 830 may be deposited using deposition processes as known by a person having ordinary skill in the art, such as PVD processes, CVD processes including PECVD processes, and ALD processes. The first dielectric layer 830 can include at least one of SiO₂, Al₂O₃, HfO₂, TiO₂, SiON, and SiN, and can have a thickness between about 50 nm and about 600 nm. If necessary, the first dielectric layer 830 may be patterned and etched using suitable techniques known in the art. The first dielectric layer 830 may serve as a gate insulating layer in a TFT.

In FIG. 8C, an oxide semiconductor layer 840 is formed in the storage capacitor region and on the first dielectric layer 830 in the TFT region. In some implementations as shown in FIG. 8C, a portion of the oxide semiconductor layer 840 in the TFT region is spaced apart from another portion of the oxide semiconductor layer 840 in the storage capacitor region. The oxide semiconductor layer 840 in the TFT region may have a source region, a drain region, and a channel region, where the channel region is between the source region and the drain region. The channel region of the oxide semiconductor layer 840 may be aligned with the first metal layer 820. Forming the oxide semiconductor layer 840 may include steps of depositing, masking, and/or etching. In some implementations, the oxide semiconductor layer 840 may be deposited using any suitable deposition technique, such as PVD. The oxide semiconductor layer 840 can include an oxide semiconductor material, such as IGZO, IZTO, ZnO, IZO, InO, or SnO, and can have a thickness between about 10 nm and about 100 nm. The oxide semiconductor material can be substantially transparent to visible light. The semiconductor layer 840 may be patterned (mask2) and etched using suitable techniques known in the art, such as a dry (e.g., plasma) etching process or a wet chemical etching process, depending in part on the material of the semiconductor layer 840. The oxide semiconductor layer 840 may serve as a semiconductor layer or active layer of a TFT in the TFT region, and as a transparent electrode of a storage capacitor in the storage capacitor region.

In FIG. 8D, a second metal layer 850 is formed on the oxide semiconductor layer 840. The second metal layer 850 is in contact with the source region and the drain region of the oxide semiconductor layer 840 in the TFT region. In addition, the second metal layer 850 is in contact with a portion of the oxide semiconductor layer 840 in the storage capacitor region. Forming the second metal layer 850 can include steps of depositing, masking, and/or etching the second metal layer 850. The second metal layer 850 may be deposited using deposition processes as known by a person having ordinary skill in the art, including PVD processes, CVD processes, and ALD processes. The second metal layer 850 can include at least one of Ti, Mo, Ta, W, Ni, Au, Cu, Al, Cr, and Nd, and can have a thickness between about 50 nm and about 600 nm. The second metal layer 850 can be patterned (mask3) and etched using suitable techniques known in the art. The second metal layer 850 can serve as source and drain electrodes 850a, 850b for a TFT in the TFT region. The source and drain electrodes 850a, 850b can be electrically connected to a data line of a display element. In some implementations, the source electrode 850a can be configured to output an output signal, where the output signal is configured to drive a display element. In some implementations, the drain electrode 850b can be configured to receive an input signal, where the input signal is configured to cause charge to be accumulated along the second metal layer 850 so that data can be stored in a storage capacitor. Moreover, the second metal layer 850 can serve as a common electrode 850c, where the common electrode 850 is electrically connected to a portion of the oxide semiconductor layer 840 in the storage capacitor region.

In FIG. 8E, a second dielectric layer 860 is formed on the second metal layer 850 and the oxide semiconductor layer 840 in the TFT region. In some implementations, the second dielectric layer 860 can cover the source electrode 850a, the drain electrode 850b, and the common electrode 850c. In some implementations, the second dielectric layer 860 is also formed on the second metal layer 850 and the oxide semiconductor layer 840 in the storage capacitor region. Forming the second dielectric layer 860 can include steps of depositing, masking, and/or etching the second dielectric layer 860. The second dielectric layer 860 can be deposited using deposition processes as known by a person of ordinary skill in the art. The second dielectric layer 860 can include at least one of SiO₂, Al₂O₃, HfO₂, TiO₂, SiON, and SiN, and can have a thickness between about 50 nm and about 300 nm. The second dielectric layer 860 can be patterned (mask4) and etched using suitable techniques known in the art. A via hole can be formed in the second dielectric layer 860 so that a portion of the oxide semiconductor layer 840 is exposed. The second dielectric layer 860 can serve as a passivation layer or protective layer for a TFT in the TFT region, and as a dielectric layer between two electrodes for a storage capacitor in the storage capacitor region.

In FIG. 8F, a transparent conductive layer 870 is formed over the oxide semiconductor layer 840 in the storage capacitor region. The transparent conductive layer 870 is at least partially overlapping with the oxide semiconductor layer 840 in the storage capacitor region. In some implementations, the transparent conductive layer 870 is formed on the second dielectric layer 860 in the storage capacitor region. As illustrated in FIG. 8F, the transparent conductive layer 870 may be electrically connected to the exposed portion of the oxide semiconductor layer 840 by a transparent via 871. Forming the transparent conductive layer 870, including the transparent via 871, can include steps of depositing, masking, and/or etching the transparent conductive layer 870. The transparent conductive layer 870 can be deposited using deposition processes as known by a person of ordinary skill in the art. The transparent conductive layer 870 can include a transparent conductive oxide, such as ITO, IZO and AZO, and can have a thickness between about 10 nm and about 300 nm. The transparent conductive layer 870 can be patterned (mask5) and etched using suitable techniques known in the art. The transparent conductive layer 870 can serve as a transparent electrode for a storage capacitor in the storage capacitor region.

In FIG. 8G, a resistance lowering process is applied to the oxide semiconductor layer 840 in at least the storage capacitor region so that the oxide semiconductor layer 840 in the storage capacitor region has a lower electrical resistance than the oxide semiconductor layer 840 in the channel region. The resistance lowering process can be applied after any operation subsequent to forming the oxide semiconductor layer 840 in FIG. 8C. In some implementations, for example, the resistance lowering process can be applied after forming the oxide semiconductor layer 840 in FIG. 8C but prior to forming the second dielectric layer 860 in FIG. 8E. In other implementations, for example, the resistance lowering process can be applied after forming the transparent conductive layer 870. After the resistance lowering process shown in FIG. 8G is performed, and after the second metal layer 850, the second dielectric layer 860, and the transparent conductive layer 870 are formed in FIGS. 8D-8F, the apparatus 800 including a TFT, a storage capacitor, and a common electrode may be fabricated. The apparatus 800 may be fabricated using fewer masks than conventionally used for fabricating TFTs adjacent to transparent storage capacitors, where the number of masks for fabricating the apparatus 800 can be five or less.

The resistance lowering process can be applied to the apparatus 800 to cause portions of the oxide semiconductor layer 840 to become conductive and form a conductive oxide. That way, rather than forming an additional electrically conductive layer, a part of the oxide semiconductor layer 840 can get converted to a transparent conductive oxide. In some implementations, as shown in FIG. 8G, the resistance lowering process includes exposing portions of the oxide semiconductor layer 840 to UV light, where the first metal layer 820 in the TFT region shields at least the channel region of the oxide semiconductor layer 840 from the UV light. The portions of the oxide semiconductor layer 840 exposed to the UV light become a transparent conductive oxide layer 840b, while the unexposed portions of the oxide semiconductor layer 840 remain as a transparent oxide semiconductor layer 840a. Without being limited by any theory, the UV light can generate oxygen vacancies in the oxide semiconductor layer 840, which act as donors and increase electron concentration, thereby decreasing the electrical resistance of the oxide semiconductor layer 840 in the storage capacitor region. The first metal layer 820 may be substantially non-transparent to UV light so that the first metal layer 820 shields at least the channel region of the oxide semiconductor layer 840 from exposure. The substrate 810 and the first dielectric layer 830, however, may be substantially transparent to UV light. By using the first metal layer 820 as a light shield, a separate mask is not needed to shield portions of the oxide semiconductor layer 840 in the channel region from exposure to UV light.

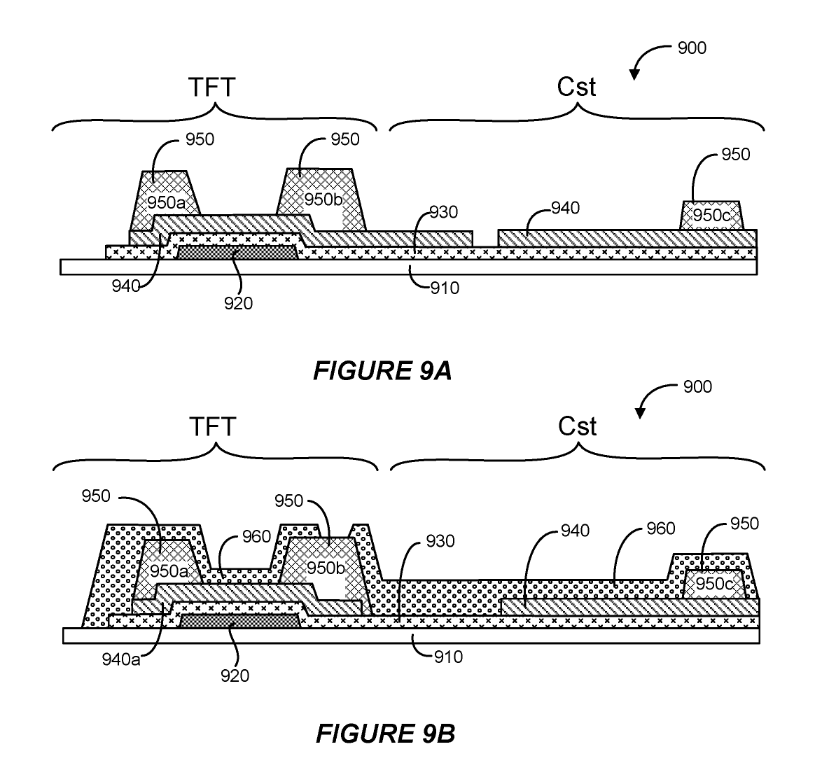

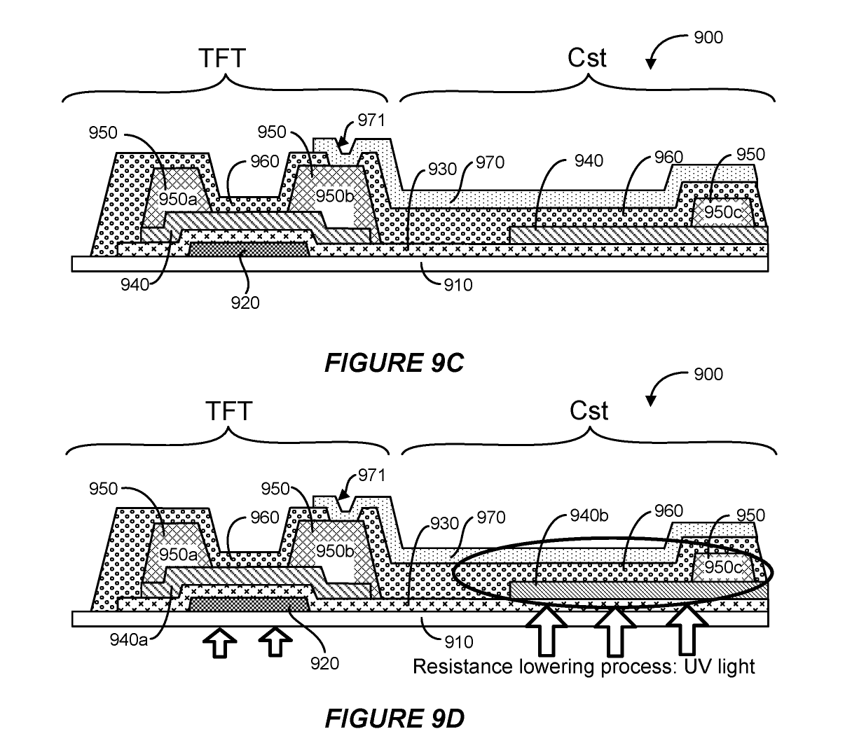

FIGS. 9A-9D show schematic cross-sectional views illustrating a process for manufacturing an apparatus including a TFT and a storage capacitor, where a transparent via is electrically connected to a drain electrode, a common electrode is formed out of the same layer as source and drain electrodes, and UV light is used for lowering an electrical resistance of portions of the oxide semiconductor layer. Accordingly, FIGS. 9A-9D illustrate a process for manufacturing the apparatus 600 shown in FIGS. 6A and 6B. The process for manufacturing the apparatus may be performed in a different order or with different, fewer, or additional operations. In some implementations, the process in FIGS. 9A-9D may illustrate a process for manufacturing a display element (e.g., pixel) for a display device.

In FIGS. 9A-9D, the apparatus 900 can have a TFT region (labeled “TFT”) and a storage capacitor region (labeled “Cst”) adjacent to the TFT region. In FIG. 9A, a substrate 910 is provided in the TFT and the storage capacitor region, a first metal layer 920 is formed on the substrate 910 in the TFT region, a first dielectric layer 930 is formed on the first metal layer 920, an oxide semiconductor layer 940 is formed in the storage capacitor region and on the first dielectric layer 930 in the TFT region, and a second metal layer 950 is formed on the oxide semiconductor layer 940. In the TFT region, the oxide semiconductor layer 940 can have a source region, a drain region, and a channel region between the source region and the drain region. The second metal layer 950 can be in contact with the source region to form a source electrode 950a and with the drain region to form a drain electrode 950b. The second metal layer 950 can also be in contact with a portion of the oxide semiconductor layer 940 in the storage capacitor region that forms a common electrode 950c. The discussion for providing or forming the substrate 810, the first metal layer 820, the first dielectric layer 830, the oxide semiconductor layer 840, and the second metal layer 850 in FIGS. 8A-8D may equally apply to providing or forming the substrate 910, the first metal layer 920, the first dielectric layer 930, the oxide semiconductor layer 940, and the second metal layer 950 in FIG. 9A. In some implementations, an etch stop layer (not shown) may be formed on the oxide semiconductor layer 940, where the etch stop layer is between the oxide semiconductor layer 940 and a second dielectric layer 960. In some implementations, the etch stop layer may be between the oxide semiconductor layer 940 and a transparent conductive layer 970 in the storage capacitor region.

In FIG. 9B, a second dielectric layer 960 is formed on the second metal layer 950 and the oxide semiconductor layer 940 in the TFT region. In some implementations, the second dielectric layer 960 can cover the source electrode 950a and the common electrode 950c. In some implementations, the second dielectric layer 960 can be formed on the second metal layer 950 and the oxide semiconductor layer 940 in the storage capacitor region. The second dielectric layer 960 in FIG. 9B can be formed in a manner similar to the second dielectric layer 860 in FIG. 8E, except that a via hole is formed in the second dielectric layer 960 so that a portion of the drain electrode 950b is exposed. The second dielectric layer 960 can serve as a passivation layer or protective layer for a TFT in the TFT region. In some implementations, the second dielectric layer 960 can serve as a dielectric layer between two electrodes for a storage capacitor in the storage capacitor region. In some implementations, a third dielectric layer (not shown) is formed on the second dielectric layer 960 in at least the TFT region. In some implementations, the third dielectric layer can be between the oxide semiconductor layer 940 and a transparent conductive layer 970 in the storage capacitor region.

In FIG. 9C, a transparent conductive layer 970 is formed over the oxide semiconductor layer 940 in the storage capacitor region. The transparent conductive layer 970 is at least partially overlapping with the oxide semiconductor layer 940 in the storage capacitor region. In some implementations, the transparent conductive layer 970 is formed on the second dielectric layer 960 in the storage capacitor region. The transparent conductive layer 970 in FIG. 9C can be formed in a manner similar to the transparent conductive layer 870 in FIG. 8F, except that the transparent conductive layer 970 is electrically connected to the exposed portion of the drain electrode 950b by a transparent via 971. The transparent conductive layer 970 can serve as a transparent electrode for a storage capacitor in the storage capacitor region.

In FIG. 9D, a resistance lowering process is applied to the oxide semiconductor layer 940 in at least the storage capacitor region so that the oxide semiconductor layer 940 in the storage capacitor region has a lower electrical resistance than the oxide semiconductor layer 940 in the channel region. The resistance lowering process can be applied after any operation subsequent to forming the oxide semiconductor layer 940. In some implementations, the resistance lowering process can include exposing at least a portion of the oxide semiconductor layer 940 in the storage capacitor region to UV light. The resistance lowering process in FIG. 9D can be performed in a manner similar to the resistance lowering process in FIG. 8G. In FIG. 9D, the UV light can transform the oxide semiconductor layer 940 in the storage capacitor region into a transparent conductive oxide layer 940b while leaving the oxide semiconductor layer 940 in the TFT region as a transparent oxide semiconductor layer 940a. After the resistance lowering process shown in FIG. 9D is performed, and after the second metal layer 950, the second dielectric layer 960, and the transparent conductive layer 970 are formed in FIGS. 9A-9C, the apparatus 900 including a TFT, a storage capacitor, and a common electrode may be fabricated. The apparatus 900 may be fabricated using fewer masks than conventionally used for fabricating TFTs adjacent to transparent storage capacitors, where the number of masks for fabricating the apparatus 900 can be five or less.

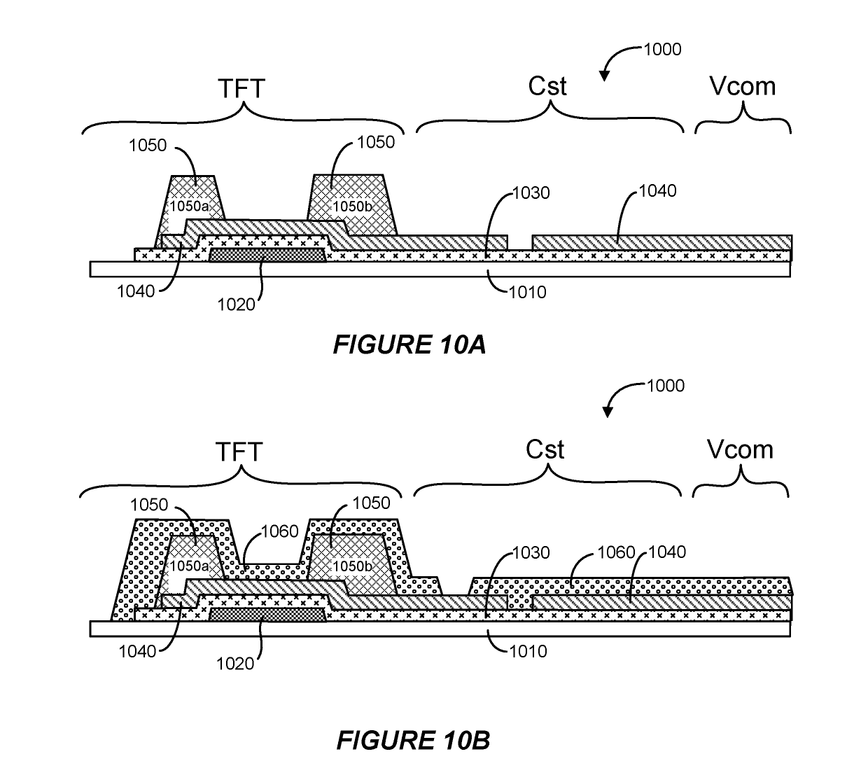

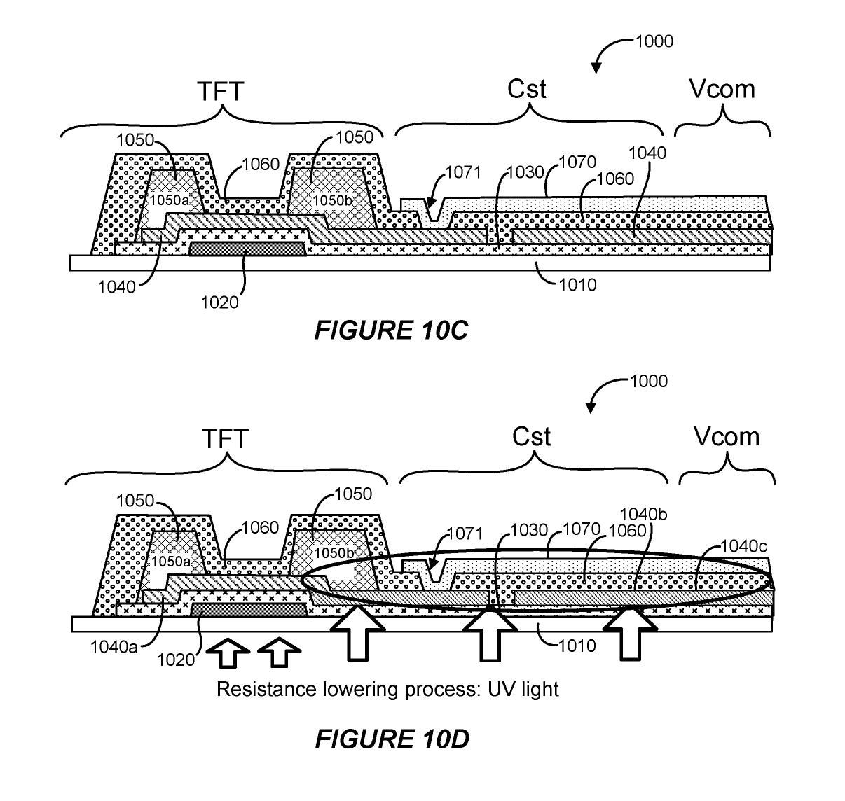

FIGS. 10A-10D show schematic cross-sectional views illustrating a process for manufacturing an apparatus including a TFT and a storage capacitor, where a transparent via is electrically connected to an oxide semiconductor layer, a common electrode is formed out of the same layer as the oxide semiconductor layer and a first transparent electrode, and UV light is used for lowering an electrical resistance of portions of the oxide semiconductor layer. Accordingly, FIGS. 10A-10D illustrate a process for manufacturing the apparatus 700 shown in FIGS. 7A and 7B. The process for manufacturing the apparatus may be performed in a different order or with different, fewer, or additional operations. In some implementations, the process in FIGS. 10A-10D may illustrate a process for manufacturing a display element (e.g., pixel) for a display device.

In FIGS. 10A-10D, the apparatus 1000 can have a TFT region (labeled “TFT”), a storage capacitor region (labeled “Cst”) adjacent to the TFT region, and a common electrode region (labeled “Vcom”) adjacent to the storage capacitor region. In FIG. 10A, a substrate 1010 is provided in the TFT, the storage capacitor, and the common electrode region, a first metal layer 1020 is formed on the substrate 1010 in the TFT region, and a first dielectric layer 1030 is formed on the first metal layer 1020. In addition, an oxide semiconductor layer 1040 is formed in the storage capacitor region and the common electrode region, and on the first dielectric layer 1030 in the TFT region. Furthermore, a second metal layer 1050 is formed on the oxide semiconductor layer 1040. In the TFT region, the oxide semiconductor layer 1040 can have a source region, a drain region, and a channel region between the source region and the drain region. The second metal layer 1050 can be in contact with the source region to form a source electrode 1050a and with the drain region to form a drain electrode 1050b. Unlike FIGS. 8A-8G and 9A-9D, the second metal layer 1050 in FIGS. 10A-10D is not formed in the storage capacitor region or the common electrode region. The discussion for providing or forming the substrate 810, the first metal layer 820, the first dielectric layer 830, and the oxide semiconductor layer 840, in FIGS. 8A-8C may equally apply to providing or forming the substrate 1010, the first metal layer 1020, the first dielectric layer 1030, and the oxide semiconductor layer 1040 in FIG. 10A.

In FIG. 10B, a second dielectric layer 1060 is formed on the second metal layer 1050 and the oxide semiconductor layer 1040 in the TFT region. In some implementations, the second dielectric layer 1060 is formed on the oxide semiconductor layer 1040 in the storage capacitor region. In some implementations, the second dielectric layer 1060 is also formed on the oxide semiconductor layer 1040 in the common electrode region. In some implementations, the second dielectric layer 1060 can cover the source electrode 1050a and the drain electrode 1050b. The second dielectric layer 1060 in FIG. 10B can be formed in a manner similar to the second dielectric layer 860 in FIG. 8E, where a via hole is formed in the second dielectric layer 1060 to expose a portion of the oxide semiconductor layer 1040. The second dielectric layer 1060 can serve as a passivation layer or protective layer for a TFT in the TFT region. In some implementations, the second dielectric layer 1060 can serve as a dielectric layer between two electrodes for a storage capacitor in the storage capacitor region.

In FIG. 10C, a transparent conductive layer 1070 is formed over the oxide semiconductor layer 1040 in the storage capacitor region. The transparent conductive layer 1070 is at least partially overlapping with the oxide semiconductor layer 1040 in the storage capacitor region. In some implementations, the transparent conductive layer 1070 is formed on the second dielectric layer 1060 in the storage capacitor region. The transparent conductive layer 1070 in FIG. 10C can be formed in a manner similar to the transparent conductive layer 870 in FIG. 8F, where the transparent conductive layer 1070 is electrically connected to the exposed portion of the oxide semiconductor layer 1040 by a transparent via 1071. The transparent conductive layer 1070 can serve as a transparent electrode for a storage capacitor in the storage capacitor region.

In FIG. 10D, a resistance lowering process is applied to the oxide semiconductor layer 1040 in at least the storage capacitor region and the common electrode region so that the oxide semiconductor layer 1040 in the storage capacitor region and the common electrode region has a lower electrical resistance than the oxide semiconductor layer 1040 in the channel region. The resistance lowering process can be applied after any operation subsequent to forming the oxide semiconductor layer 1040. In some implementations, the resistance lowering process can include exposing at least a portion of the oxide semiconductor layer 1040 in the storage capacitor region to UV light. The resistance lowering process in FIG. 10D can be performed in a manner similar to the resistance lowering process in FIG. 8G, where the gate electrode 1020 can act as a light shield. In FIG. 10D, the UV light can transform the oxide semiconductor layer 1040 into a first transparent conductive oxide 1040b in the storage capacitor region and a second transparent conductive oxide 1040c in the common electrode region. The oxide semiconductor layer 1040 in the TFT region can remain as a transparent oxide semiconductor layer 1040a. After the resistance lowering process shown in FIG. 10D is performed, and after the second metal layer 1050, the second dielectric layer 1060, and the transparent conductive layer 1070 are formed in FIGS. 10A-10C, the apparatus 1000 including a TFT, a storage capacitor, and a common electrode may be fabricated. The apparatus 1000 may be fabricated using fewer masks than conventionally used for fabricating TFTs adjacent to transparent storage capacitors, where the number of masks for fabricating the apparatus 1000 can be five or less.

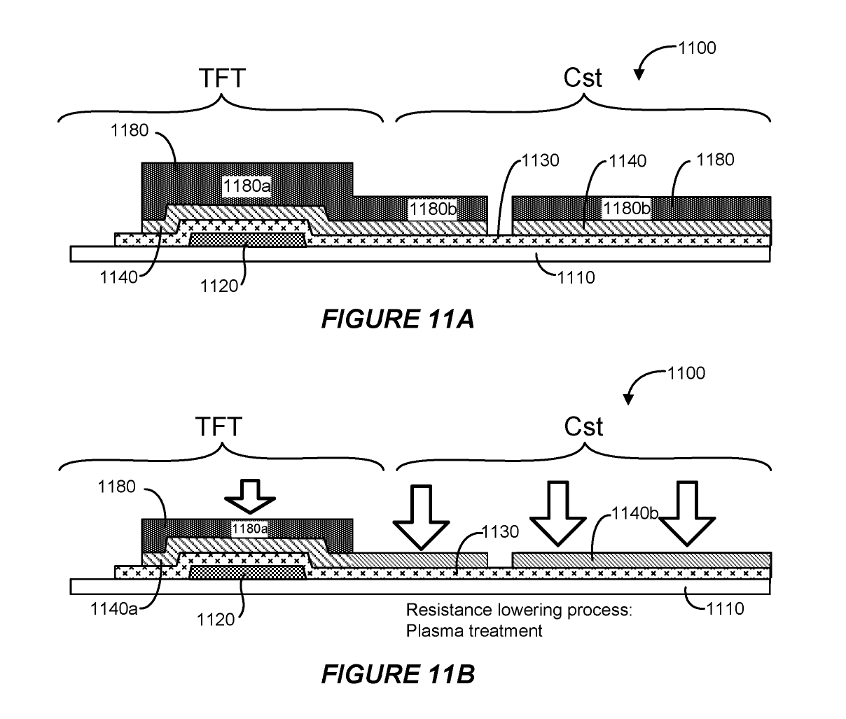

FIGS. 11A and 11B show schematic cross-sectional views illustrating a process for lowering an electrical resistance of portions of an oxide semiconductor layer using a plasma treatment. Rather than exposing portions of an oxide semiconductor layer to UV light as shown in FIGS. 8G, 9D, and 10D, a plasma treatment can transform portions of the oxide semiconductor layer to a transparent conductive oxide. Without being limited by any theory, the plasma treatment can generate oxygen vacancies in the oxide semiconductor layer. Thus, portions of the oxide semiconductor layer exposed to plasma have a lower electrical resistance than portions of the oxide semiconductor layer that are not exposed to plasma.

In FIGS. 11A and 11B, an apparatus 1100 can have a TFT region (labeled “TFT”) and a storage capacitor region (labeled “Cst”) adjacent to the TFT region. In some implementations, the apparatus 1100 can have a common electrode region (not shown) adjacent to the storage capacitor region. In FIG. 11A, a substrate 1110 is provided, a first metal layer 1120 is formed on the substrate 1110 in the TFT region, and a first dielectric layer 1130 is formed on the first metal layer 1120. In addition, an oxide semiconductor layer 1140 is formed in the storage capacitor region and on the first dielectric layer 1130 in the TFT region. In some implementations, a space can separate a portion of the oxide semiconductor layer 1140 from another portion of the oxide semiconductor layer 1140. The discussion for providing or forming the substrate 810, the first metal layer 820, the first dielectric layer 830, and the oxide semiconductor layer 840, in FIGS. 8A-8C may equally apply to providing or forming the substrate 1110, the first metal layer 1120, the first dielectric layer 1130, and the oxide semiconductor layer 1140 in FIG. 11A. A half-tone mask 1180 can be formed over the oxide semiconductor layer 1140, where the half-tone mask 1180 can have different thicknesses. A half-tone mask 1180 can be semi-transmissive to light. By using a half-tone mask 1180 of different thicknesses, such as three different thicknesses, fewer masks are used and fewer cycles of photolithography may be applied. This can result in a simplified manufacturing process and reduced costs. Here, in FIG. 11A, the half-tone mask 1180 can have a thicker portion 1180a above the oxide semiconductor layer 1140 in the TFT region, and can have a thinner portion 1180b above the oxide semiconductor layer 1140 in the storage capacitor region.

In FIG. 11B, the thinner portion 1180b of the half-tone mask 1180 in at least the storage capacitor region may be removed. In some implementations, the thinner portion 1180b of the half-tone mask 1180 may be removed by ashing, while some of the thicker portion 1180a remains over the oxide semiconductor layer 1140 in the TFT region. At least the oxide semiconductor layer 1140 in the storage capacitor region can be exposed after removal of the thinner portion 1180b of the half-tone mask 1180. Afterwards, a plasma treatment can be applied to the exposed portion of the oxide semiconductor layer 1140 in the storage capacitor region. The thicker portion 1180a of the half-tone mask can act as a shield against the plasma treatment in at least some of the TFT region. The plasma treatment can transform the oxide semiconductor layer 1140 into a transparent conductive oxide 1140b in the storage capacitor region, while at least some of the oxide semiconductor layer 1140 in the TFT region can remain as a transparent oxide semiconductor layer 1140a. After the resistance lowering process in FIG. 11B is performed, remaining operations may be performed to form a second metal layer (not shown), a second dielectric layer (not shown), and a transparent conductive layer (not shown) to form an apparatus including a TFT, a storage capacitor, and a common electrode, similar to the apparatuses shown in FIGS. 8A-8G, 9A-9D, and 10A-10D. The plasma treatment shown in FIGS. 11A and 11B can substitute for the resistance lowering process shown in FIGS. 8A-8G, 9A-9D, and 10A-10D. In some implementations, the plasma treatment may be performed prior to forming the second dielectric layer in the processes described in FIGS. 8A-8G, 9A-9D, and 10A-10D. In some implementations, the plasma treatment may be performed prior to forming an etch stop layer or during etch stop layer patterning. While resistance lowering processes described herein include UV irradiation and plasma treatment, a person of ordinary skill in the art will appreciate that other resistance lowering processes can be applied, such as ion implantation, annealing, etc.

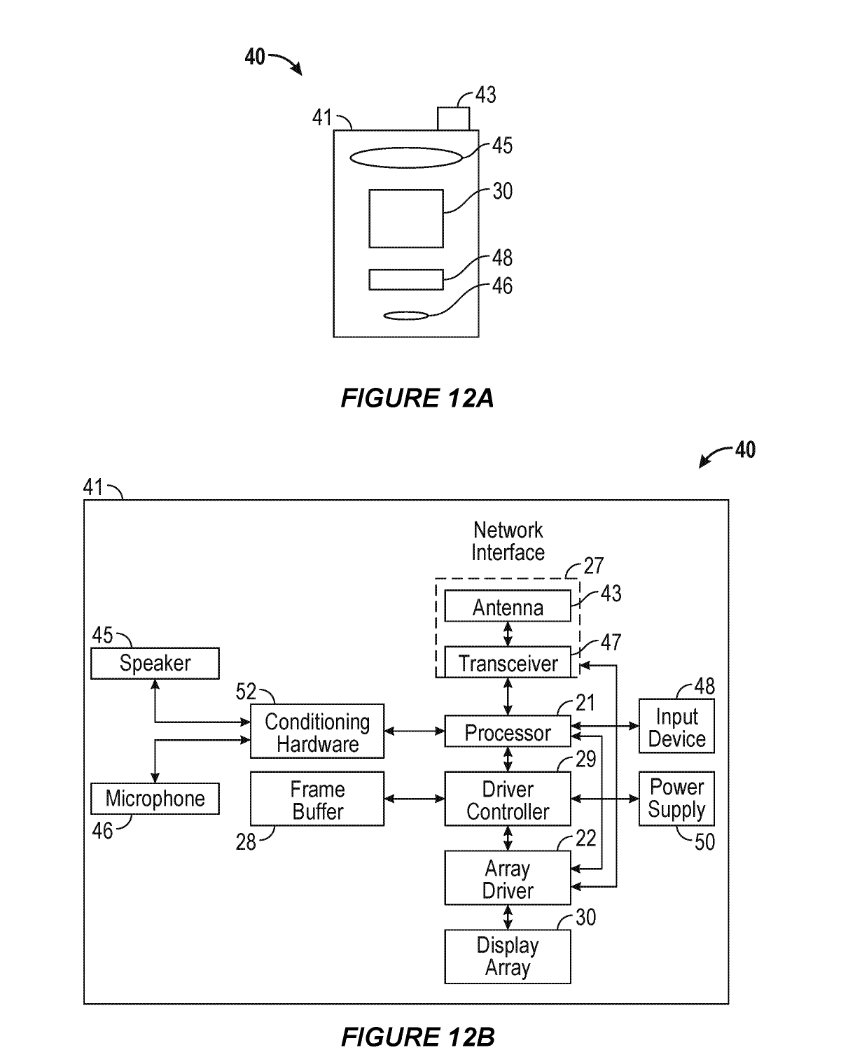

FIGS. 12A and 12B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 12B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 12A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower,” “front” and “behind,” “above” and “below” and “over” and “under,” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
(i) a substrate;
(ii) a thin film transistor (TFT) including:
a gate electrode over the substrate;
an oxide semiconductor layer, wherein the oxide semiconductor layer has a channel region between a source region and a drain region;
a first insulating layer between the gate electrode and the oxide semiconductor layer;
a source electrode on a source region of the oxide semiconductor layer;
a drain electrode on a drain region of the oxide semiconductor layer; and
a dielectric layer over the channel region of the oxide semiconductor layer;
(iii) a storage capacitor adjacent to the TFT and including:
a first transparent electrode over the substrate, wherein the first transparent electrode has a substantially similar thickness and composition as the oxide semiconductor layer;
a second transparent electrode over the first transparent electrode and at least partially overlapping with the first transparent electrode; and
a second insulating layer between the first transparent electrode and the second transparent electrode; and
(iv) a common electrode, wherein the common electrode is electrically connected to the first transparent electrode.

2. The apparatus of claim 1, wherein the common electrode has a substantially similar thickness and composition as the source and drain electrodes.

3. The apparatus of claim 1, wherein the common electrode has a substantially similar thickness and composition as the oxide semiconductor layer.

4. The apparatus of claim 1, wherein the second transparent electrode is electrically connected to the oxide semiconductor layer by a transparent via.

5. The apparatus of claim 1, wherein the second transparent electrode is electrically connected to the drain electrode by a transparent via.

6. The apparatus of claim 1, wherein the oxide semiconductor layer and the first transparent electrode include at least one of indium-gallium-zinc-oxide (IGZO), indium-zinc-tin-oxide (IZTO), zinc oxide (ZnO), indium-zinc-oxide (IZO), indium oxide (InO), and tin oxide (SnO).

7. The apparatus of claim 1, wherein the second transparent electrode includes at least one of indium-tin-oxide (ITO), indium-zinc-oxide (IZO), and aluminum-doped zinc oxide (AZO).

8. The apparatus of claim 1, wherein the first transparent electrode and the oxide semiconductor layer share a first common thin film layer, and wherein the common electrode and the source and drain electrodes share a second common thin film layer.

9. The apparatus of claim 1, wherein the first transparent electrode, the oxide semiconductor layer, and the common electrode share a common thin film layer.

10. The apparatus of claim 1, wherein the first transparent electrode is directly connected to the common electrode and is not electrically connected to the source and drain electrodes.

11. The apparatus of claim 1, wherein the first transparent electrode has a lower electrical resistance than the oxide semiconductor layer in the channel region.

12. The apparatus of claim 1, wherein the drain region of the oxide semiconductor layer have a lower electrical resistance than the oxide semiconductor layer in the channel region.

13. The apparatus of claim 1, wherein the substrate includes at least one of glass, polyethylene terephthalate (PET), and polyethylene naphthalate (PEN).

14. The apparatus of claim 1, wherein the storage capacitor and the substrate are substantially transparent to visible light, and wherein the gate electrode is substantially non-transparent to ultraviolet and visible light.

15. The apparatus of claim 1, wherein the dielectric layer and the second insulating layer share a common thin film layer.

16. The apparatus of claim 1, further comprising:
an etch stop layer on the oxide semiconductor layer, wherein the etch stop layer is between the oxide semiconductor layer and the dielectric layer.

17. The apparatus of claim 1, further comprising:
a plurality of display elements, wherein the common electrode is configured to apply a common voltage to each of the plurality of display elements, the apparatus being a display device comprising the plurality of display elements.

18. The apparatus of claim 17, further comprising:
a processor that is configured to communicate with one or more display elements, the processor being configured to process image data; and
a memory device that is configured to communicate with the processor.

19. The apparatus of claim 18, further comprising:
a driver circuit configured to send at least one signal to one or more display elements; and
a controller configured to send at least a portion of the image data to the driver circuit.

20. The apparatus of claim 18, further comprising:
an image source module configured to send the image data to the processor, wherein the image source module comprises at least one of a receiver, transceiver, and transmitter.

21. The apparatus of claim 18, further comprising:
an input device configured to receive input data and to communicate the input data to the processor.

22. A method of manufacturing an apparatus, the apparatus having a TFT region and a storage capacitor region adjacent to the TFT region, the method comprising:
providing a substrate in the TFT and the storage capacitor region;
forming a first metal layer on the substrate in the TFT region;
forming a first dielectric layer on the first metal layer;
forming an oxide semiconductor layer in the storage capacitor region and on the first dielectric layer in the TFT region, wherein the oxide semiconductor layer in the TFT region has a channel region between a source region and a drain region;
forming a second metal layer on the oxide semiconductor layer, the second metal layer in contact with the source region and the drain region, and the second metal layer in contact with a portion of the oxide semiconductor layer in the storage capacitor region;
forming a second dielectric layer on the second metal layer and the oxide semiconductor layer in the TFT region;
forming a transparent conductive layer over the oxide semiconductor layer in the storage capacitor region, the transparent conductive layer at least partially overlapping with the oxide semiconductor layer in the storage capacitor region; and
applying, after any operation subsequent to forming the oxide semiconductor layer, a resistance lowering process to the oxide semiconductor layer in the storage capacitor region so that the oxide semiconductor layer in the storage capacitor region has a lower electrical resistance than the oxide semiconductor layer in the channel region.

23. The method of claim 22, wherein applying the resistance lowering process includes exposing at least a portion of the oxide semiconductor layer to ultraviolet light.

24. The method of claim 22, wherein applying the resistance lowering process includes treating at least a portion of the oxide semiconductor layer with plasma prior to forming the second dielectric layer.

25. The method of claim 22, wherein the transparent conductive layer is electrically connected to the second metal layer or the oxide semiconductor layer by a transparent via.

26. The method of claim 22, wherein the oxide semiconductor layer includes at least one of IGZO, IZTO, ZnO, IZO, InO, and SnO, and the transparent conductive layer includes at least one of ITO, IZO, and AZO.

27. The method of claim 22, wherein the second metal layer contacting the portion of the oxide semiconductor layer in the storage capacitor region is a common electrode.

28. A method of manufacturing an apparatus, the apparatus having a TFT region, a storage capacitor region adjacent to the TFT region, and a common electrode region adjacent to the storage capacitor region, the method comprising:
providing a substrate in the TFT, the storage capacitor, and the common electrode region;
forming a first metal layer on the substrate in the TFT region;
forming a first dielectric layer on the first metal layer;
forming an oxide semiconductor layer in the storage capacitor region and the common electrode region and on the first dielectric layer in the TFT region, wherein the oxide semiconductor layer in the TFT region has a channel region between a source region and a drain region;
forming a second metal layer on the oxide semiconductor layer, the second metal layer in contact with the source region and the drain region;
forming a second dielectric layer on the second metal layer and the oxide semiconductor layer in the TFT region;
forming a transparent conductive layer over the oxide semiconductor layer in the storage capacitor region, the transparent conductive layer at least partially overlapping with the oxide semiconductor layer in the storage capacitor region; and
applying, after any operation subsequent to forming the oxide semiconductor layer, a resistance lowering process to the oxide semiconductor layer in the storage capacitor region and the common electrode region so that the oxide semiconductor layer in the storage capacitor region and the common electrode region has a lower electrical resistance than the oxide semiconductor layer in the TFT region.

29. The method of claim 28, wherein applying the resistance lowering process includes exposing at least a portion of the oxide semiconductor layer to ultraviolet light.

30. The method of claim 28, wherein applying the resistance lowering process includes treating at least a portion of the oxide semiconductor layer with plasma prior to forming the second dielectric layer.

31. The method of claim 28, wherein the transparent conductive layer is electrically connected to the second metal layer or the oxide semiconductor layer by a transparent via.

32. The method of claim 28, wherein the oxide semiconductor layer includes at least one of IGZO, IZTO, ZnO, IZO, InO, and SnO, and the transparent conductive layer includes at least one of ITO, IZO, and AZO.
